(19) United States
(12) Patent Application Publication
(10) Pub. No.: US 2026/0169376 A1
(43) Pub. Date: Jun. 18, 2026

(54) IMPRINT APPARATUS, IMPRINT METHOD, EXPOSURE APPARATUS, AND MANUFACTURING METHOD OF ARTICLE

(71) Applicant: CANON KABUSHIKI KAISHA, Tokyo (JP)

(72) Inventors: MASAKI ISHIDA, Tochigi (JP); KIYOHITO YAMAMOTO, Tochigi (JP)

(21) Appl. No.: 19/395,373

(22) Filed: Nov. 20, 2025

(30) Foreign Application Priority Data
Dec. 16, 2024 (JP) 2024-220250

(51) Int. Cl. G03F 7/00; G03F 7/16; G03F 7/20; G03F 9/00

(52) U.S. Cl. CPC G03F 7/0002; G03F 7/168; G03F 7/2012; G03F 9/7042; G03F 9/7046

(57) ABSTRACT

An imprint apparatus performing an imprint process of forming a pattern in a curable composition on a substrate by using a mold, the imprint apparatus has a coating unit that applies the curable composition to the substrate on which a first alignment mark is formed, a driving unit that drives at least one of the mold on which a second alignment mark is formed and the substrate, an irradiation unit that irradiates light for curing the curable composition, a restricting unit that restricts an irradiation range of light irradiated from the irradiation unit; and a control unit that, after the imprint process, performs control such that the coating unit applies the curable composition to a first alignment-mark portion, the restricting unit restricts an irradiation range to the first alignment-mark portion, and the irradiation unit irradiates the light to form a protection pattern that protects the first alignment mark.

### BACKGROUND

### Field of the Technology

The present disclosure relates to an imprint apparatus, an imprint method, an exposure apparatus, and a manufacturing method of an article.

### Description of the Related Art

In the manufacture of semiconductor devices and the like, an imprint apparatus employing imprint technology is known, in which a liquid such as an uncured resin is discharged from a nozzle onto a substrate, and a mold (also referred to as a template) having an uneven pattern is pressed against the discharged resin to form a predetermined pattern. In such an imprint apparatus, precise overlay is performed by detecting an alignment signal obtained by irradiating detection light, which passes through the mold, onto patterns provided on the mold and the substrate that serve as marks for alignment. Thus, an article having a fine structure in the order of a few nanometers can be formed.

In the formation of a circuit pattern of a semiconductor device, overlay accuracy between a circuit pattern already formed on a substrate and a circuit pattern to be formed is extremely important.

In an imprint apparatus employing imprint technology, the die-by-die overlay scheme is adopted as an overlay scheme between the substrate and the mold. The die-by-die overlay scheme is a scheme in which a pattern (an overlay mark) formed on the substrate and serving for overlay and an overlay mark formed on the mold side are optically detected, and a positional deviation between the substrate and the mold is corrected. Therefore, overlay marks (also referred to as “overlay patterns”) need to be formed for each imprint region on both the substrate and the mold.

As device circuit patterns become finer, overlay marks are reduced in size, and their visibility tends to deteriorate. Japanese Unexamined Patent Application Publication No. 2019-41126 discloses a proposal in which a recessed structure of an alignment mark (overlay mark) of an imprint template (mold) is formed deeper than a recessed structure of a transfer pattern.

In the die-by-die overlay scheme, since overlay marks need to be formed for each imprint region, it is necessary to arrange a large number of overlay marks on the substrate.

For example, an overlay mark on the substrate used during the first-layer imprint is shaved and deformed by etching and therefore cannot be used for the imprinting of the second and subsequent layers. Therefore, an overlay mark to be used in the second layer needs to be provided in a region different from that of the overlay mark used in the first layer. Accordingly, a drawback arises in that the region required for arranging overlay marks on the substrate increases in size.

Additionally, in the method described in Japanese Unexamined Patent Application Publication No. 2019-41126, since a recessed portion of an alignment mark is formed deeper than a concave portion of a transfer pattern serving as a circuit pattern, the number of processes for manufacturing the mold increases compared to the conventional case, resulting in an increase in cost. Additionally, since the alignment mark is formed deeper than the transfer pattern, during imprinting, the amount of filling of a fluid such as a resin differs between the alignment mark and the transfer pattern, and the adjustment of a discharge amount and a discharge position of the fluid becomes complicated.

### SUMMARY

The present disclosure is directed to provide a technology for minimizing the region of an overlay mark on the substrate side, for example, during imprinting.

According to an aspect of the present disclosure, an imprint apparatus is configured to perform an imprint process of forming a pattern in a curable composition on a substrate by using a mold. The imprint apparatus comprises: a coating unit configured to apply the curable composition to the substrate on which a first alignment mark has been formed; a driving unit configured to drive at least one of the mold on which a second alignment mark has been formed and the substrate; an irradiation unit configured to irradiate light for curing the curable composition; a restricting unit configured to restrict an irradiation range of the light irradiated from the irradiation unit; and a control unit configured to, after the imprint process, perform control such that the coating unit applies the curable composition to the first alignment-mark portion, the restricting unit restricts the irradiation range to the first alignment-mark portion, and the irradiation unit irradiates the light to form a protection pattern that protects the first alignment mark.

Features of the present disclosure will become apparent from the following description of embodiments with reference to the attached drawings. The following description of embodiments is described by way of example.

### BRIEF DESCRIPTION OF THE DRAWINGS

FIG. 1 is a diagram illustrating a basic configuration of an imprint apparatus.

FIG. 2 is a diagram illustrating a mold in a conventional imprint apparatus.

FIGS. 3A and 3C are diagrams illustrating processing steps in a conventional imprint apparatus.

FIG. 4 is a diagram illustrating an imprint apparatus according to a first embodiment.

FIG. 5 is a diagram illustrating a mold used in the imprint apparatus of FIG. 4.

FIGS. 6A and 6C are diagrams illustrating a method for forming a protection pattern in the imprint apparatus of FIG. 4.

FIGS. 7A and 7B are diagrams illustrating a method for forming a protection pattern in the imprint apparatus of FIG. 4.

FIGS. 8A and 8C are diagrams illustrating a method for forming a protection pattern in the imprint apparatus of FIG. 4.

FIG. 9 is a flowchart illustrating an imprint sequence in the imprint apparatus of FIG. 4.

FIG. 10 is a diagram illustrating an imprint apparatus according to a second embodiment.

FIG. 11 is a diagram illustrating an example of an irradiated region on a substrate.

FIG. 12 is a diagram illustrating an example of an order of imprinting.

FIG. 13 is a flowchart illustrating an imprint sequence in the imprint apparatus of FIG. 10.

FIG. 14 is a diagram illustrating a resin coating method in the imprint sequence of FIG. 13.

FIG. 15 is a diagram illustrating an exposure method in the imprint sequence of FIG. 13.

FIG. 16 is a diagram illustrating an exposure apparatus according to a third embodiment.

FIG. 17 is a diagram illustrating an original used in the exposure apparatus of FIG. 16.

FIG. 18 is a flowchart illustrating a protection-pattern forming sequence in the exposure apparatus of FIG. 16.

FIGS. 19A and 19C are diagrams illustrating a method for forming a protection pattern in the exposure apparatus of FIG. 16.

FIGS. 20A and 20F are diagrams for explaining a manufacturing method of an article.

### DESCRIPTION OF THE EMBODIMENTS

### First Embodiment

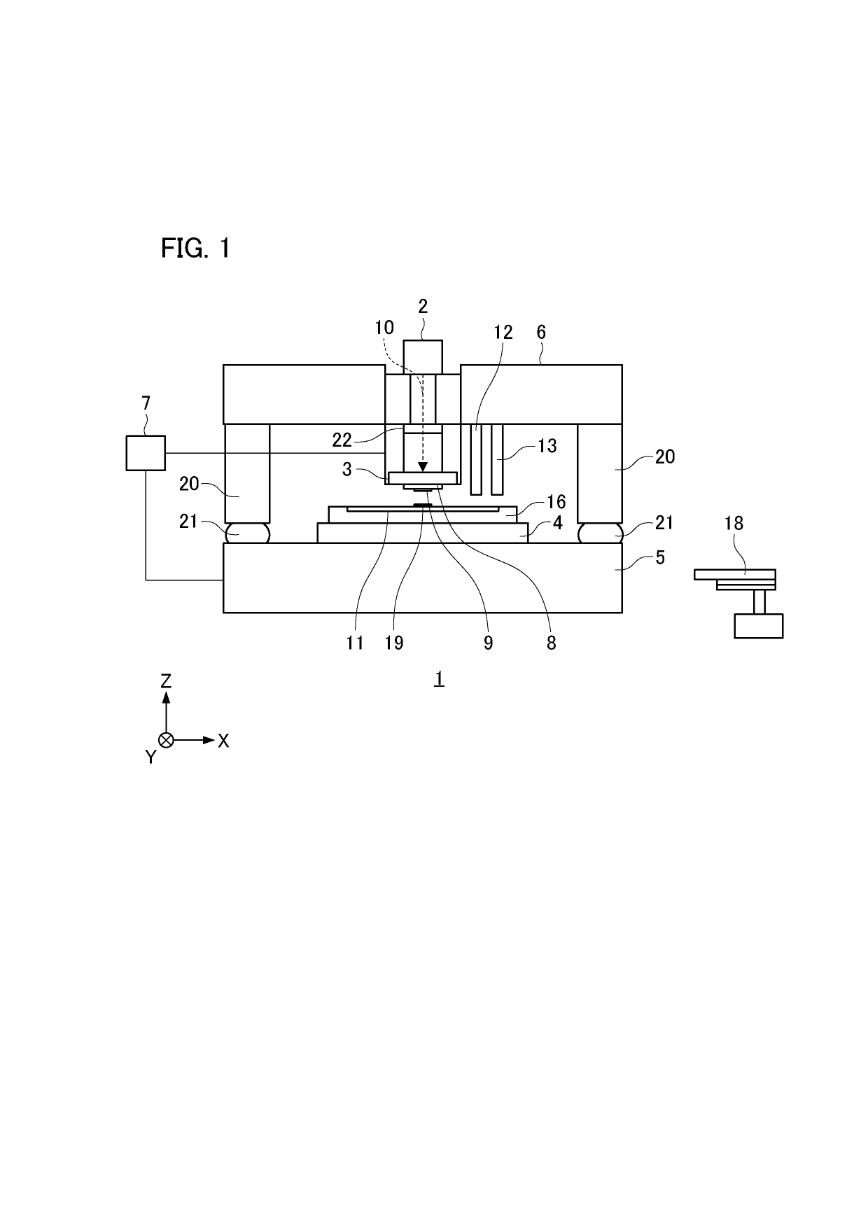

Hereinafter, a first embodiment will be explained. FIG. 1 is a diagram illustrating a basic configuration of an imprint apparatus 1. The imprint apparatus 1 can be used for manufacturing an article typified by a device such as a semiconductor device. The imprint apparatus 1 brings a mold 8 into contact with an uncured resin 19 (imprint material) applied (supplied) to an imprint region of a substrate 11 and forms a resin pattern by curing the resin 19 in a state in which the mold 8 is in contact with the resin 19. That is, the imprint apparatus 1 performs, with respect to an imprint region of the substrate 11, an imprint processing (hereinafter simply referred to as “imprint”) of forming a pattern in a curable composition on the substrate 11 by using a mold.

Curing of the resin 19 is carried out, for example, by irradiating the resin 19 with light 10 such as ultraviolet light in a state in which the mold 8 is brought into contact with the resin 19. Note that in the drawings shown hereinafter, including FIG. 1, a Z axis is defined in parallel with the optical axis of a light irradiation unit 2 that irradiates the resin 19 on the substrate 11 with the light 10, and X and Y axes orthogonal to each other are defined in a plane perpendicular to the Z axis.

The imprint apparatus 1 is provided with a light irradiation unit 2, a mold holding unit 3, a substrate stage 4, a control unit 7, a coating unit 12, an overlay measurement unit 13, and a mold driving mechanism 22. The light irradiation unit 2 irradiates the resin 19 with the light 10 through the mold 8 during imprinting. The light irradiation unit 2 may include, for example, a light source and an optical element that adjusts the light 10 emitted from the light source into light suitable for imprinting.

The mold 8 has, for example, an outer peripheral shape that is rectangular. A pattern region 9 is formed on a surface of the mold 8 that faces the substrate 11.

The mold 8 is held by a mold holding unit 3. The mold holding unit 3 holds the mold 8 by attracting an outer peripheral region of an irradiation surface of the mold 8 for the light 10 with a vacuum suction force or an electrostatic force. For example, in a case in which the mold holding unit 3 holds the mold 8 by a vacuum suction force, the mold holding unit 3 is connected to a vacuum pump (not illustrated) installed externally, and attachment and detachment of the mold 8 can be switched by turning ON and OFF this vacuum pump.

The mold driving mechanism 22 performs an operation of driving the mold 8 so as to bring the mold 8 into contact with the resin 19 on the substrate 11, and an operation of driving the mold 8 so as to separate the mold 8 from the cured resin 19. That is, the mold driving mechanism 22 functions as a driving unit that drives the mold 8. The mold driving mechanism 22 may include, for driving the mold 8, an actuator such as a linear motor or an air cylinder. The mold driving mechanism 22 may be configured by a plurality of driving systems such as a coarse motion system and a fine driving system so as to cope with high-precision positioning of the mold 8. The mold driving mechanism 22 may have functions of adjusting positions in the X-axis direction and the Y-axis direction, rotation about the Z axis, and tilt, in addition to a position in the Z-axis direction.

It should be noted that the operation of bringing the mold 8 into contact with the resin 19 and the operation of separating the mold 8 from the cured resin 19 may be realized by moving the mold 8 in the Z-axis direction. Alternatively, the operation of bringing the mold 8 into contact with the resin 19 and the operation of separating the mold 8 from the cured resin 19 may be realized by moving the substrate stage 4 in the Z-axis direction, or by moving both the mold 8 and the substrate stage 4.

The substrate 11 is, for example, a single-crystal silicon substrate or a Silicon on Insulator (SOI) substrate. On a surface (processing target surface) of the substrate 11, an uncured resin 19 that is cured upon irradiation with light 10 such as ultraviolet light is applied. The resin 19 is applied to an imprint region on the substrate 11 on which imprinting is to be performed.

The substrate stage 4 holds the substrate 11 and performs alignment between the mold 8 and the resin 19 on the substrate 11 when bringing the mold 8 into contact with the resin 19. The substrate stage 4 has a substrate holding unit 16 that holds the substrate 11 by an attraction force, and an actuator (not illustrated) that drives the substrate holding unit 16 in each axial direction. Examples of the actuator include a linear motor and a planar motor. Similarly to the mold driving mechanism 22, the substrate stage 4 may be configured by a plurality of driving systems such as a coarse motion system and a fine driving system with respect to directions of the X axis and the Y axis. Additionally, the substrate stage 4 may have a driving system for position adjustment in the Z-axis direction, an adjustment function for rotation (ωz) about the Z axis of the substrate 11, and a tilt function for correcting a tilt (ωx, ωy) of the substrate 11. That is, the substrate stage 4 functions as a driving unit that drives the substrate 11.

The coating unit (also referred to as a “dispenser”) 12 is installed in the vicinity of the mold holding unit 3, and applies an uncured resin 19, as an imprint material, onto the substrate 11. Here, the amount of the resin 19 discharged from the coating unit 12 is determined based on a target film thickness of the resin 19 to be applied on the substrate 11, and a density of a resin pattern to be formed.

In the present embodiment, as the imprint material, it is possible to use a curable composition that is cured by being supplied with curing energy. Examples of curing energy include electromagnetic waves and the like. As an electromagnetic wave, for example, light such as infrared light, visible light, and ultraviolet light, having a wavelength selected from a range of 10 nm or more and 1 mm or less, is used. In the present embodiment, an example will be explained in which ultraviolet light is used as the curing energy. That is, in the present embodiment, the resin 19 is a photocurable resin that is cured by receiving light 10 such as ultraviolet light from the light irradiation unit 2.

The curable composition is a composition that cures by irradiation with light. A photocurable composition that is cured by irradiation with light contains at least a polymerizable compound and a photopolymerization initiator, and may contain, as necessary, a non-polymerizable compound or a solvent. The non-polymerizable compound is at least one selected from the group consisting of a sensitizer, a hydrogen donor, an internally added release agent, a surfactant, an antioxidant, and a polymer component.

The overlay measurement unit 13 measures a positional deviation or a shape deviation between the mold 8 and the substrate 11.

The control unit 7 controls operations and adjustments of respective components of the imprint apparatus 1. The control unit 7 is configured by, for example, a computer (information processing apparatus) including a CPU and a memory, and is connected to the respective components of the imprint apparatus 1 via communication lines. The control unit 7 executes control of the respective components according to a program and the like, and controls, for example, operations of the mold driving mechanism 22 and the substrate stage 4. The control unit 7 may be disposed together with other portions of the imprint apparatus 1 (in a shared housing), or may be disposed separately from other portions of the imprint apparatus 1 (in a separate housing).

The imprint apparatus 1 further comprises a base platen 5 supporting the substrate stage 4, a bridge platen 6 supporting the mold holding unit 3, and a column 20 extending from the base platen 5 to support the bridge platen 6 via a vibration isolator 21. The vibration isolator 21 reduces vibrations that are transmitted from the floor surface to the bridge platen 6. Furthermore, the imprint apparatus 1 may include a substrate conveyance mechanism 18 that conveys the substrate 11 to the substrate holding unit 16 and conveys the substrate 11 from the substrate holding unit 16 to outside the imprint apparatus 1, and a mold transfer mechanism (not illustrated) that transfers the mold 8 to the mold holding unit 3.

Hereinafter, an imprint sequence performed by the imprint apparatus 1 will be explained. In the imprint sequence to be explained below, the control unit 7 controls a series of operations. The control unit 7 first controls the substrate conveyance mechanism 18 to convey the substrate 11 onto the substrate holding unit 16, and to cause the substrate holding unit 16 to hold the substrate 11. Next, to apply the resin 19 to an imprint region of the substrate 11 to be imprinted, the control unit 7 moves the substrate stage 4 so that the imprint region moves under the coating unit 12. Next, the control unit 7 controls the coating unit 12 to apply the resin 19 to the substrate 11. Next, the control unit 7 moves the substrate stage 4 so that the imprint region on which the resin 19 has been applied on the substrate 11 is positioned directly under the pattern region 9 of the mold 8.

Next, the control unit 7 controls the mold driving mechanism 22 to bring the mold 8 into contact with the resin 19 on an imprint region of the substrate 11 to be imprinted. Thus, the resin 19 is filled into the textured portion of the pattern region 9 of the mold 8. In this state, the control unit 7 controls the light irradiation unit 2 to irradiate the light 10 onto the resin 19 through the mold 8, thereby curing the resin 19. After curing of the resin 19, the control unit 7 controls the mold driving mechanism 22 to separate the mold 8 from the cured resin 19. Thus, the pattern region 9 of the mold 8 is transferred onto the resin 19 applied to the substrate 11. Such a series of imprint processes is carried out for a plurality of imprint regions formed on the substrate 11.

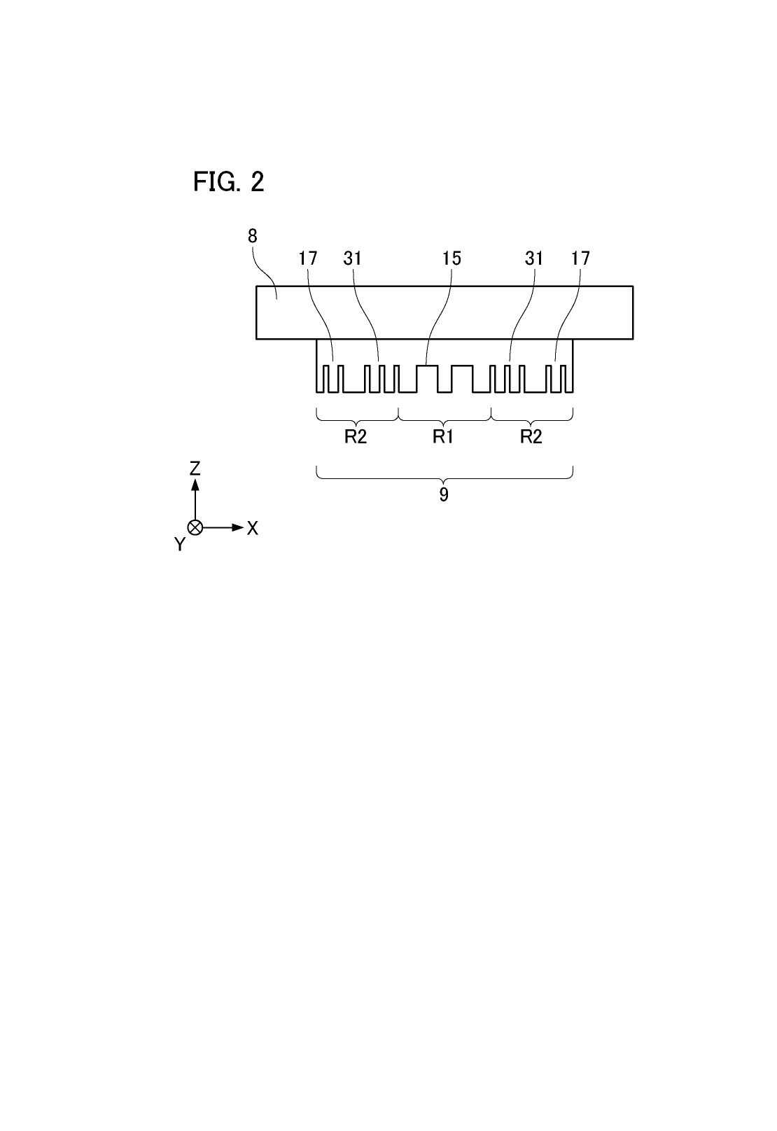

FIG. 2 illustrates an example of a configuration of the mold 8. The pattern region 9 formed in the mold 8 includes a main pattern region R1 in which a main pattern 15 to be transferred, such as a circuit pattern, is formed, and an overlay pattern region R2. In the overlay pattern region R2, a mold-side overlay pattern 17 for alignment with an overlay pattern formed on the substrate 11 is formed, and a pattern 31 for alignment of the mold 8 when imprinting to form a second layer is formed. A material of the mold 8 is a material capable of transmitting the light 10, for example, quartz.

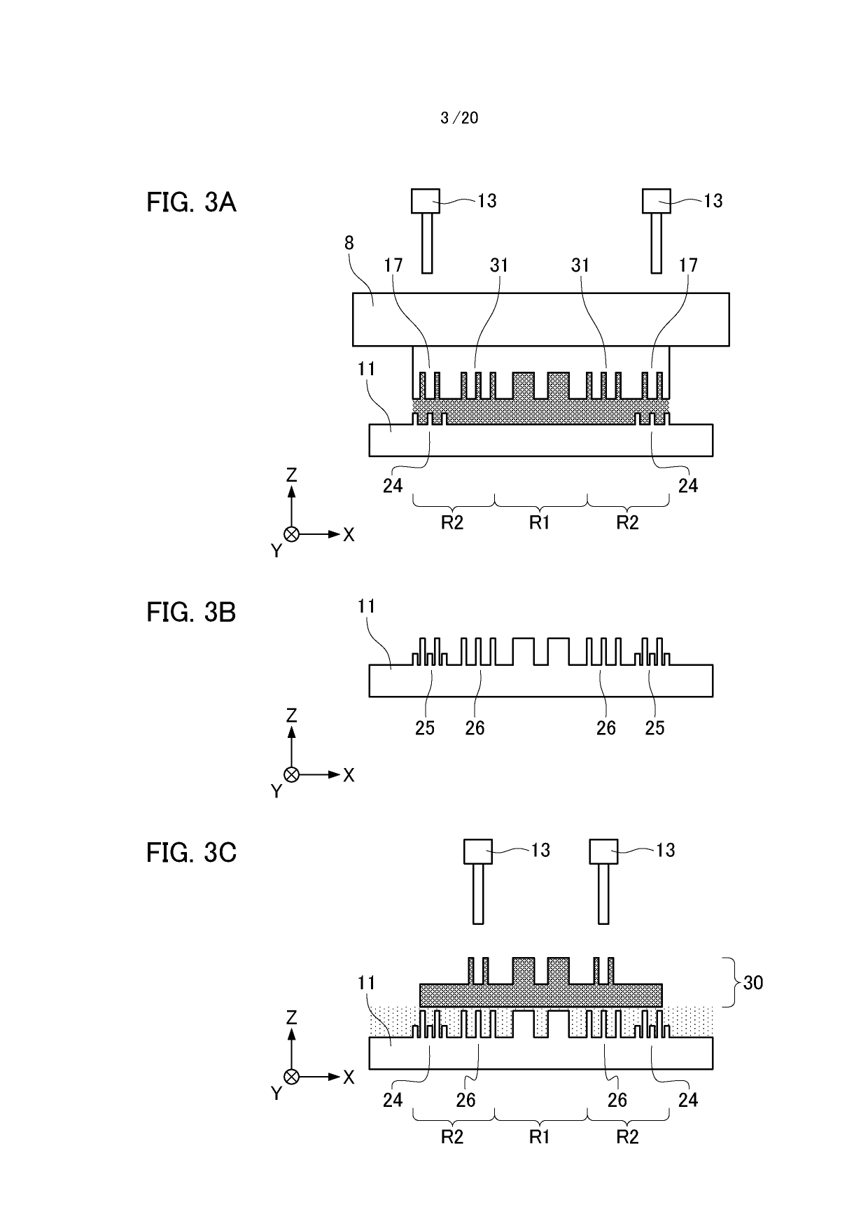

Here, with reference to FIGS. 3A and 3C, conventional imprint steps are explained. First, as shown in FIG. 3A, the overlay measurement unit 13 measures positional and shape deviations between the mold-side overlay pattern 17 of the mold 8 and a substrate-side overlay pattern 24 formed on the substrate 11. The substrate-side overlay pattern 24 functions as a first alignment mark formed on the substrate 11. Then, after alignment between the mold 8 and the imprint region is performed based on the measurement result, a resin pattern is formed by curing the resin 19 in that state. Here, in an etching step, the substrate-side overlay pattern 24 is etched based on the shape of a main pattern formed on the substrate 11, and becomes a deformed pattern 25 as shown in FIG. 3B. Since the pattern 25 is deformed from the original substrate-side overlay pattern 24, the deformed pattern 25 cannot be used for alignment between the mold 8 and the substrate 11.

Conventionally, as shown in FIG. 3C, in a case in which an upper layer 30 is formed again by imprint after performing processing such as etching and film formation, a pattern 26 serving as a pattern for alignment with the substrate 11 has been formed in place of the substrate-side overlay pattern 24. Therefore, the region of the overlay pattern region R2 becomes larger, and the region R1 in which the main pattern 15 to be transferred, such as a circuit pattern, is formed becomes narrower.

Accordingly, in the present embodiment, after performing imprinting, a protection pattern for protecting the substrate-side overlay pattern 24 is formed by applying the resin 19 to the substrate-side overlay pattern 24 and curing the resin 19 using the light irradiation unit, thereby preventing the substrate-side overlay pattern 24 from being deformed during an etching process. Details will be explained below.

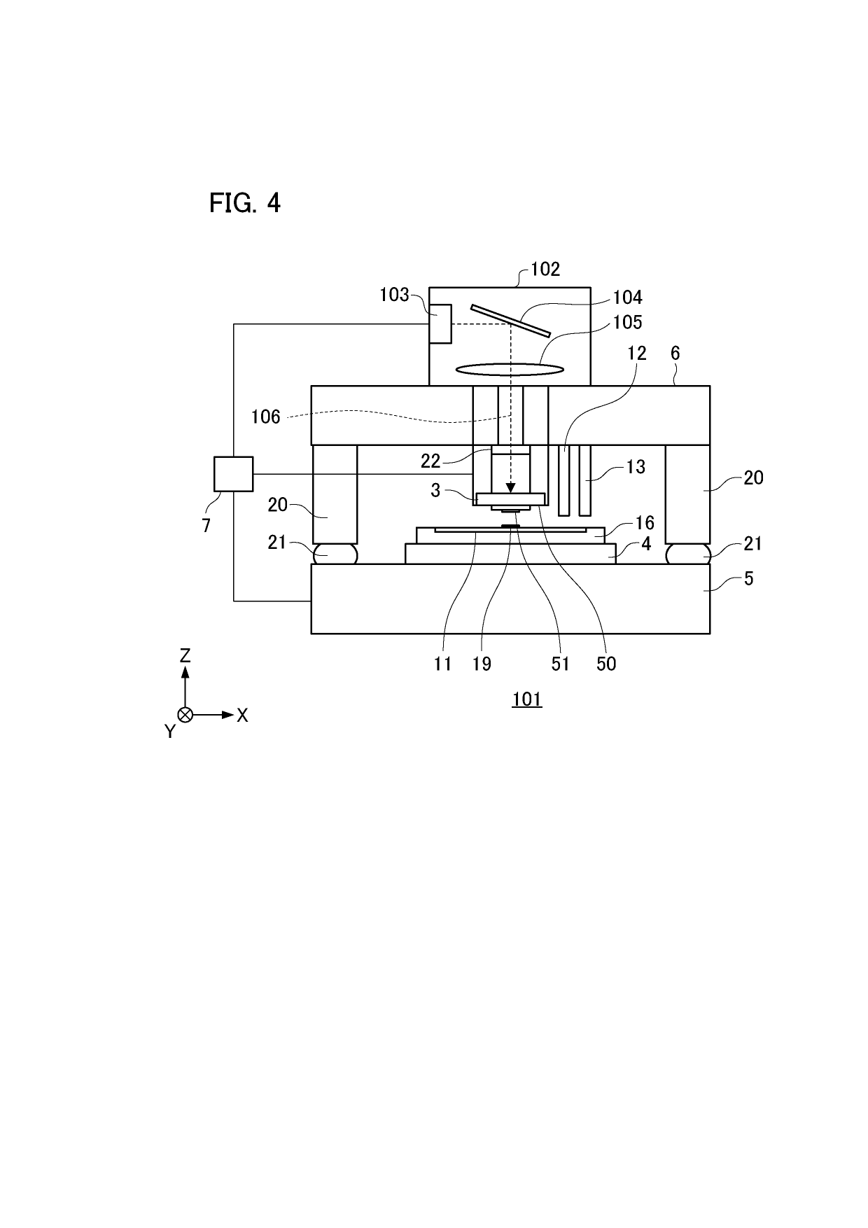

First, an apparatus configuration of an imprint apparatus used in the present embodiment will be explained with reference to FIG. 4. It should be noted that portions similar to those in FIG. 1 are denoted by the same reference numerals, and explanation thereof will be omitted. An imprint apparatus 101 differs from the imprint apparatus 1 of FIG. 1 in that the light irradiation unit 2 has been replace with a light irradiation unit 102.

The light irradiation unit 102 may include a light source 103 that generates light having a wavelength capable of curing the resin 19, which is a photo-curable composition, and a light modulation device 104 for controlling irradiation conditions of the light with respect to the resin 19 on the substrate 11. The light modulation device 104 is disposed in an optical path between the light source 103 and the mold 50, and modulates the light emitted from the light source 103. The resin 19 disposed on the substrate 11 can be irradiated with light 106 modulated by the light modulation device 104. The light modulation device 104 may be configured by, for example, a Digital Micromirror Device (DMD).

A DMD is a known device (light modulating element) in which a large number of movable micro-mirrors are arranged in a plane. The DMD can irradiate only arbitrary locations on the substrate 11 with light by controlling micro-mirrors that reflect light from the light source 103 toward the substrate 11 and micro-mirrors that block the light. It should be noted that, as the light modulation device 104, a shutter may be used to irradiate only a specific range with light, in place of the DMD. Alternatively, the light source 103 may be configured with a plurality of miniature LEDs instead of the light modulation device 104, and the irradiated region may be varied by switching the LEDs to be turned on.

Additionally, the light irradiation unit 102 may include an optical system 105 that adjusts an illuminance distribution. The optical system 105 may be configured, for example, to adjust the depth of focus of light that is irradiated through the light modulation device 104.

In the light irradiation unit 102, the light modulation device 104 is controlled by the control unit 7 such that light is irradiated only onto arbitrary locations within a specific imprint region to cure the resin 19. That is, the light modulation device 104 functions as a restricting unit that restricts the irradiation region of light emitted from the light irradiation unit 102.

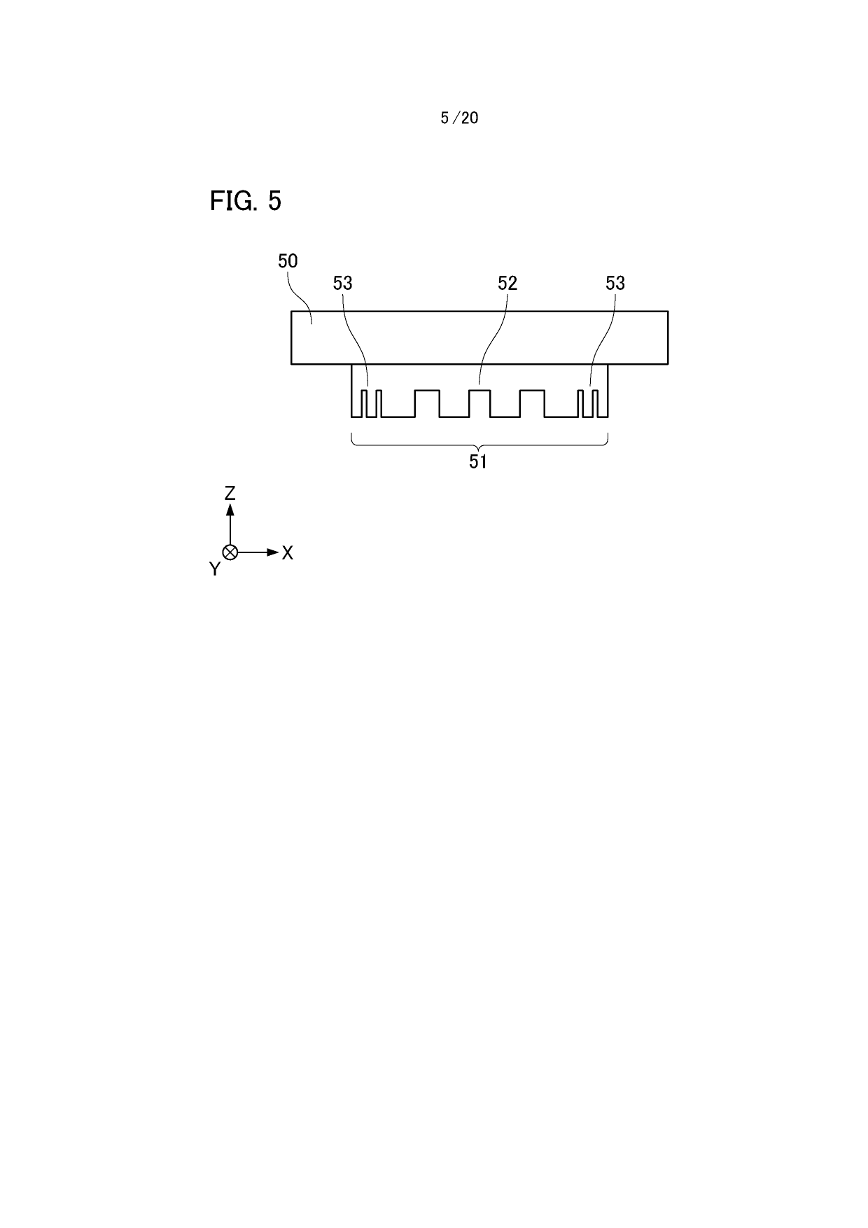

FIG. 5 is a diagram illustrating an example of the mold 50 used in the imprint apparatus 101. A pattern region 51 is formed in the mold 50, the pattern region 51 including a main pattern 52 and a mold-side overlay pattern 53. The main pattern 52 is a pattern to be transferred, such as a circuit pattern. The mold-side overlay pattern 53 is a pattern used for aligning with the substrate-side overlay pattern 24 formed on the substrate 11. That is, the mold-side overlay pattern 53 functions as a second alignment mark that is formed on the mold. It should be noted that the substrate-side overlay pattern 24 serving as the first alignment mark is the same as that shown in FIGS. 3A and 3C described above. In the mold 50 shown in FIG. 5, a pattern corresponding to the pattern 31 formed in the mold 8 shown in FIG. 2 is not formed.

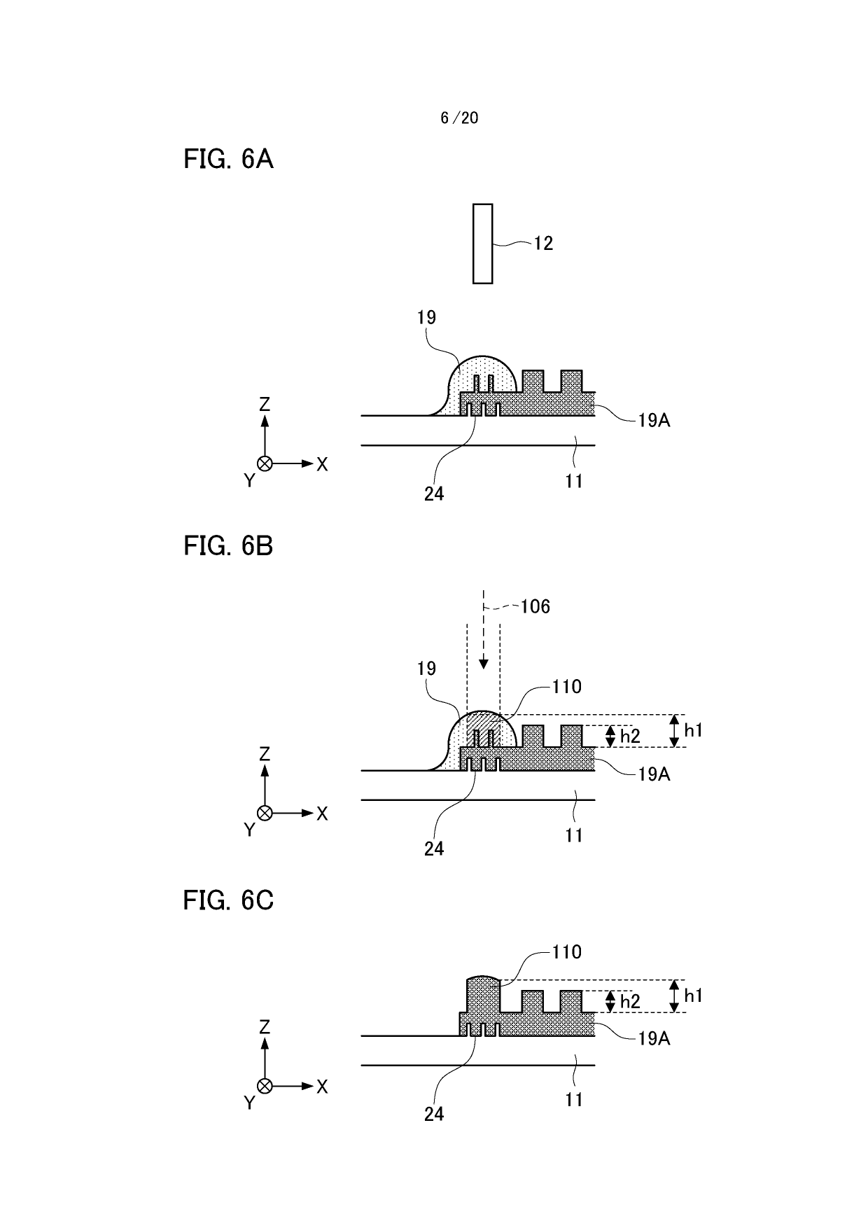

Next, a method of forming a protection pattern on the overlay pattern 24 will be explained with reference to FIGS. 6A and 6C, which is divided into a method of applying the resin 19 and a method of irradiating the light 106. The following is a method for forming a protection pattern 110 on the substrate-side overlay pattern 24 in a specific imprint region onto which a pattern has been transferred.

On the substrate 11, in the imprint region, a predetermined pattern is formed by cured resin 19A by carrying out imprinting. The coating unit 12 discharges the resin 19 onto a position directly above the substrate-side overlay pattern 24 in the Z-axis direction within the imprinted region (FIG. 6A). Then, as shown in FIG. 6B, the resin 19 newly applied is irradiated with light 106 and thereby cured.

A discharge amount of the resin 19 is determined by the size of the substrate-side overlay pattern 24 and the wettability of the resin 19 newly applied onto the cured resin 19A. Specifically, as shown in FIG. 6C, the discharge amount may be such that a formed protection pattern 110 completely covers the substrate-side overlay pattern 24 in the X-axis and Y-axis directions. Furthermore, the discharge amount may be such that a pattern height h1 (hereinafter referred to as “protection-pattern height”) of the protection pattern 110 is higher than a pattern height h2 (hereinafter referred to as “main-pattern height”) of the pattern formed by the imprint processing.

The discharge amount necessary for the protection pattern 110 to cover the substrate-side overlay pattern 24 in the X-axis and Y-axis directions may be determined by confirming, using an optical microscope (not illustrated) provided in the imprint apparatus 101, an area of the newly applied resin 19 and feeding back the result. Additionally, wettability may be confirmed by measuring a contact angle by dropping uncured resin 19 onto the cured resin 19A, and the discharge amount may be determined by performing a simulation based on the result thereof.

A discharge amount necessary to set the protection-pattern height h1 higher than the main-pattern height h2 may be determined by feeding back the protection-pattern height measured using a spectroscopic interferometric laser displacement meter (not illustrated) provided in the imprint apparatus 101. Alternatively, the discharge amount may be determined by feeding back the protection-pattern height measured using a film-thickness measuring instrument provided outside the imprint apparatus 101.

Alternatively, similarly to the above-described adjustment of the discharge amount for covering the substrate-side overlay pattern 24, the discharge amount may be determined by measuring a contact angle by dropping uncured resin 19 onto the cured resin 19A to confirm wettability, and performing a simulation based on the result.

By using the above methods, a discharge amount is determined so as to form the protection pattern 110 that covers the substrate-side overlay pattern 24 in the X-axis and Y-axis directions and has a protection-pattern height h1 higher than the main-pattern height h2. Note that, as described above, the resin 19 may completely cover the substrate-side overlay pattern 24 in the X-axis and Y-axis directions, although at least a discharge amount is sufficient as long as the substrate-side overlay pattern 24 is protected to a degree that allows alignment even after an etching process. By completely covering the substrate-side overlay pattern 24 with the protection pattern 110, the substrate-side overlay pattern 24 can remain intact even after etching, thereby enabling alignment of a second layer with the same accuracy as a first layer. Additionally, by making the protection-pattern height h1 higher than the main-pattern height h2, it is possible to prevent the substrate-side overlay pattern 24 from being etched by etching.

In a case in which a protection pattern 110 having a desired area cannot be formed by adjustment of the discharge amount, the wetting spread of the newly applied resin 19 and the area of the resin 19 due to volatilization may be adjusted by changing the time interval from coating of the resin 19 to irradiation with the light 106.

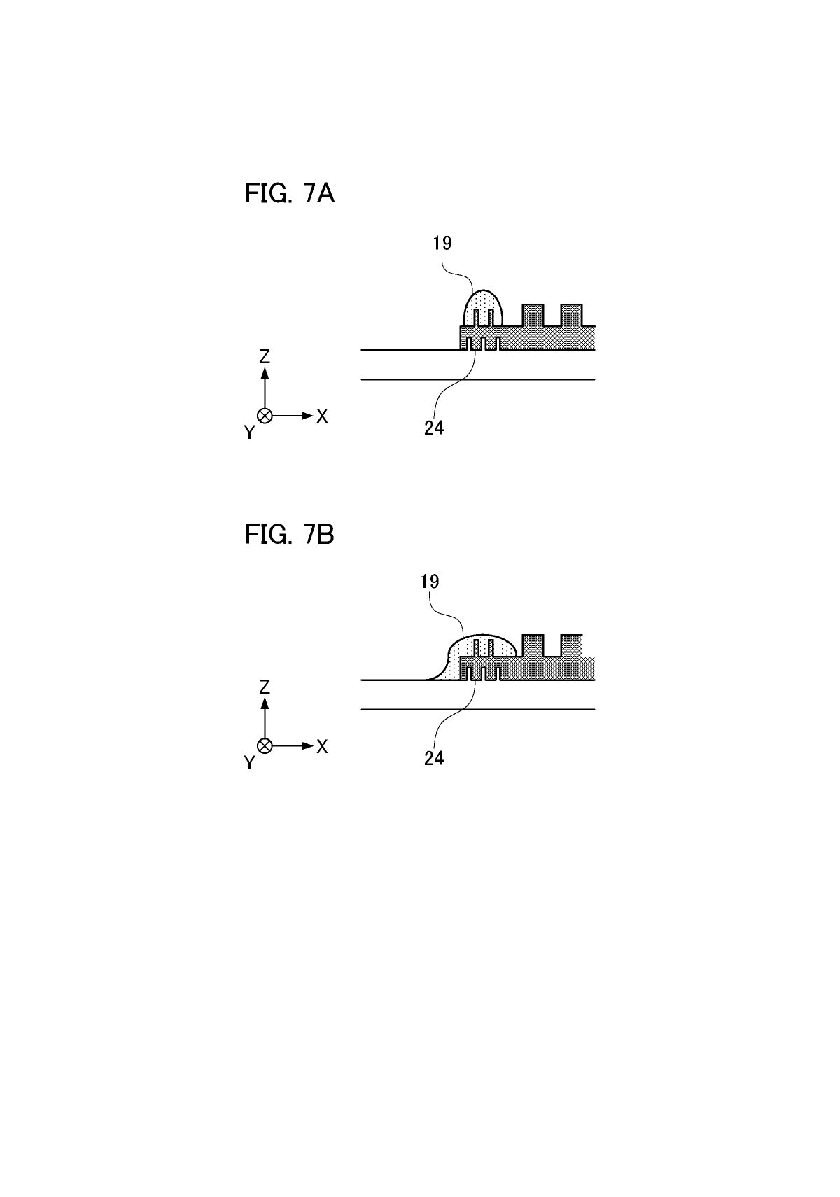

For example, as shown in FIG. 7A, in a case in which the area of the coated resin 19 is small and the coverage of the substrate-side overlay pattern 24 is insufficient, the area of coverage over the substrate-side overlay pattern 24 may be increased by delaying irradiation with the light 106. For example, as shown in FIG. 7B, after coating, irradiation may be performed after the resin 19 has spread in the X-axis and Y-axis directions to cover the substrate-side overlay pattern 24 completely. Here, the area covering the substrate-side overlay pattern 24 refers to an area on the XY plane. In short, the time interval from coating of the resin 19 to irradiation with the light 106 may be changed (adjusted) according to the area of the substrate-side overlay pattern 24 that is covered by the resin 19. Additionally, the volume of the resin 19 may be increased by performing coating of the resin 19 a plurality of times.

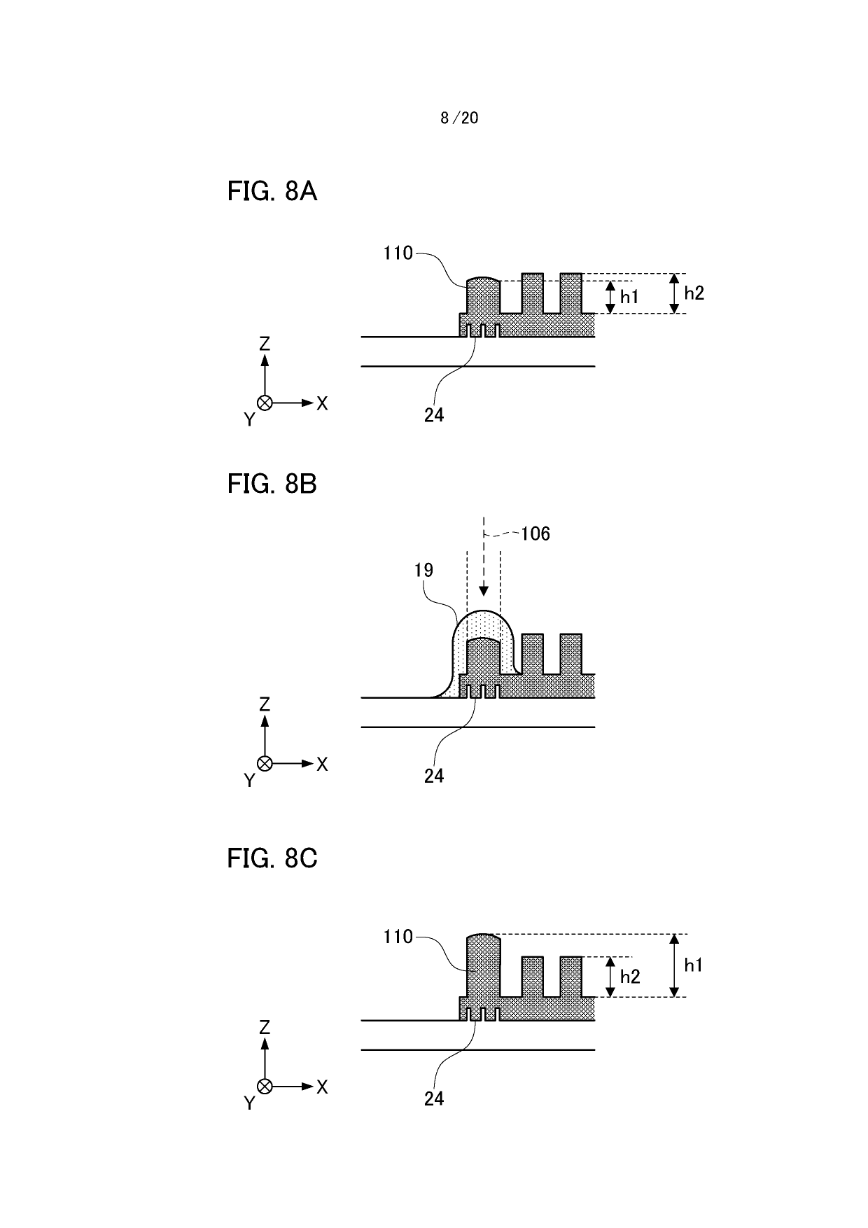

Additionally, as shown in FIG. 8A, in a case in which the protection-pattern height h1 is lower than the main-pattern height h2, as shown in FIG. 8B, coating and curing of the resin 19 may be performed again at the same location to form the protection pattern in layers in the Z-axis direction. Accordingly, as shown in FIG. 8C, the protection-pattern height h1 can be increased. That is, after formation of the protection pattern, the coating unit may again apply the curable composition to the first alignment mark portion, and the restricting unit may irradiate light onto the first alignment mark portion while limiting the irradiation region thereto. Alternatively, by adjusting the solvent ratio in the resin 19 to change its viscosity, the wettability of the resin 19 newly applied onto the cured resin may be adjusted.

Next, a method of forming the protection pattern 110 by irradiating the resin 19 with the light 106 is explained. As shown in FIG. 6B, the resin 19 applied to the substrate-side overlay pattern 24 is cured by irradiation with the light 106. At this time, by limiting (restricting) the irradiation region of the light 106 to only a region of the substrate-side overlay pattern 24, only the resin 19 directly above the substrate-side overlay pattern 24 is cured, thereby forming the protection pattern 110. Specifically, the control unit 7 controls the light modulation device 104 to limit the irradiation region of the light 106 to only the region of the substrate-side overlay pattern 24.

The resin 19 in a portion not irradiated remains uncured and disappears through volatilization, thereby preventing the cured protection pattern 110 from contacting an adjacent main pattern and affecting the main-pattern shape. That is, the protection pattern 110 is formed such that it does not overlap the pattern region formed by the imprint processing.

In the present embodiment, to protect the substrate-side overlay pattern 24, the protection-pattern height h1 is set higher than the main-pattern height h2, although setting the protection-pattern height h1 higher is not essential. For example, in a case in which deformation of the substrate-side overlay pattern 24 during etching can be prevented by making the etching resistance of the protection pattern 110 higher than that of the main pattern, the protection-pattern height h1 may be lower than the main-pattern height h2.

Specifically, when forming the protection pattern 110, the etching resistance of the protection pattern 110 may be increased relative to that of the main pattern by setting the exposure amount of the light 106 for curing the resin 19 to be greater than that for curing the resin 19 during imprinting.

Thus, by forming the protection pattern 110 on the substrate-side overlay pattern 24, it is possible to prevent deformation of the substrate-side overlay pattern 24, for example, due to being etched during an etching process. By protecting the substrate-side overlay pattern 24, it becomes possible to reuse the substrate-side overlay pattern 24 during imprinting for forming second and subsequent layers. Therefore, it becomes possible to suppress narrowing of a region in which the main pattern is formable due to a region in which the overlay pattern is formed. Furthermore, on the side of the mold 50 as well, formation of an overlay pattern for imprinting second and subsequent layers is not required.

That is, in the present embodiment, after the imprint processing, control is performed such that the coating unit applies the curable composition to the first-alignment-mark portion, the restricting unit restricts the irradiation region to the first-alignment-mark portion, and the light irradiation unit 102 irradiates light onto the first-alignment-mark portion to form a protection pattern that protects the first alignment mark.

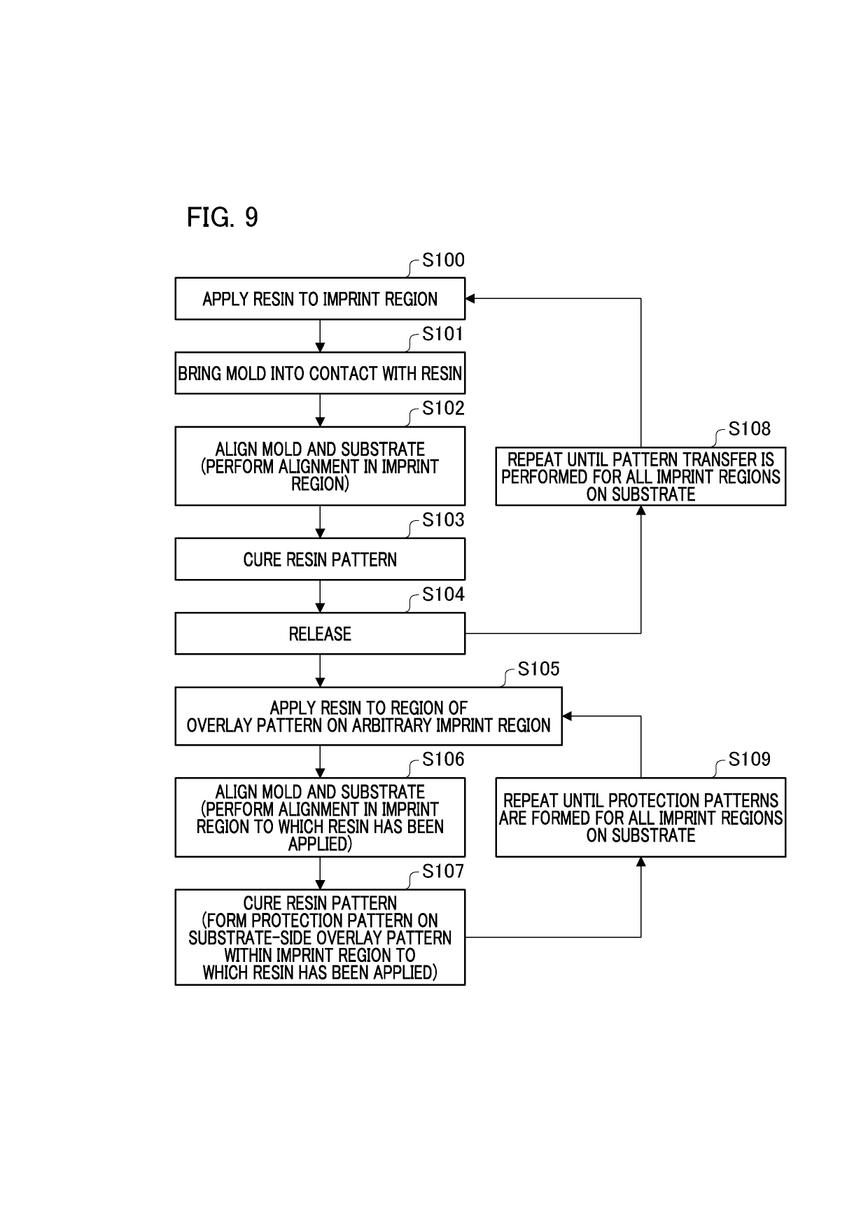

Finally, an imprint sequence (imprint method) in the present embodiment will be explained with reference to FIG. 9. In FIG. 9, in step S100, the coating unit 12 applies the resin 19 to a region to be imprinted among a plurality of imprint regions of the substrate 11 (hereinafter, referred to as a “first imprint region” in the explanation of FIG. 9).

In step S101, the substrate stage 4 moves so that the first imprint region to which the resin 19 has been applied is positioned under the mold 50, and the mold 50 is brought into contact with the resin 19 on the first imprint region by the mold driving mechanism 22. As a result, the resin 19 is filled in the concave portions of the pattern region 51 of the mold 50.

In step S102, the overlay measurement unit 13 measures the relative position between the mold-side overlay pattern 53 of the mold 50 and the substrate-side overlay pattern 24 formed on the substrate 11. The control unit 7 moves the substrate stage 4 based on the measurement results to perform alignment between the pattern region 51 of the mold 50 and the first imprint region.

In step S103, light is irradiated onto the resin 19 through the mold 50 to cure the resin 19.

In step S104, the mold driving mechanism 22 separates the mold 50 from the cured resin 19A (release), thereby transferring the pattern in the mold 50 to the first imprint region.

As described above, steps S100 to S104 are performed for all imprint regions on the substrate 11 so as to transfer a pattern of the mold 50 onto the substrate 11 (step S108). That is, step S100 functions as a coating step, step S102 functions as a driving step, and step S103 functions as an irradiation step.

Hereinafter, a sequence for forming the protection pattern 110 will be explained. In step S105, the resin 19 is applied by the coating unit 12 to an arbitrary imprint region (hereinafter, in the following explanation of FIG. 9, referred to as a “second imprint region”) to which the pattern has been transferred. At this time, as shown in FIG. 6A, based on the above-described protection-pattern forming method, the resin 19 is applied only onto the region of the substrate-side overlay pattern 24.

In step S106, the substrate stage 4 is moved so that the second imprint region is positioned under the mold 50. Then, the overlay measurement unit 13 measures the relative position between the mold-side overlay pattern 53 of the mold 50 and the substrate-side overlay pattern 24 formed in the imprint region on which the resin 19 has been newly applied. The control unit 7 moves the substrate stage 4 based on the measurement results to perform alignment between the mold 50 and the second imprint region.

In the imprint apparatus 101 of the present embodiment, due to the configuration of imprint apparatus 101, the relative position between the light irradiation unit 102 and the mold holding unit 3 or the mold driving mechanism 22 does not change. Therefore, by aligning the substrate 11 and the mold 50, the light 106 modulated by the light modulation device 104 included in the light irradiation unit 102 can be irradiated onto a desired position. However, the imprint apparatus 101 may include a mechanism capable of directly aligning the light irradiation unit 102 with the substrate 11, and in that case, step S106 is changed to the step of aligning the light irradiation unit 102 with the substrate 11.

In step S107, as shown in FIG. 6B, the light 106 is irradiated only onto a portion directly above the substrate-side overlay pattern 24 within the second imprint region to which the resin 19 has been newly applied, thereby curing the resin 19. Thus, the protection pattern 110 is formed only directly above the substrate-side overlay pattern 24 within the second imprint region, and the uncured resin 19 disappears through volatilization.

Steps S105 to S107 are performed for all imprint regions on the substrate 11 to form the protection pattern 110 (step S109). That is, steps S105 to S107 function as a protection-pattern forming step.

Thus, by forming the protection pattern 110 on the substrate-side overlay pattern 24, it becomes possible to prevent deformation of the substrate-side overlay pattern 24, for example, due to the overlay pattern 24 being scraped during the etching process.

Note that although in the present embodiment, formation of the protection pattern 110 is carried out in the imprint apparatus, formation of the protection pattern 110 may be carried out at another station of the same apparatus or by using another apparatus having the same mechanism.

### Second Embodiment

Next, a second embodiment is explained. In the first embodiment, for a specific imprint region, after performing imprinting, the protection pattern 110 is formed by applying the resin 19 again to an overlay pattern portion and curing the resin 19. In contrast, in the present embodiment, a method will be explained in which the process time is shortened by simultaneously performing imprinting and formation of the protection pattern 110.

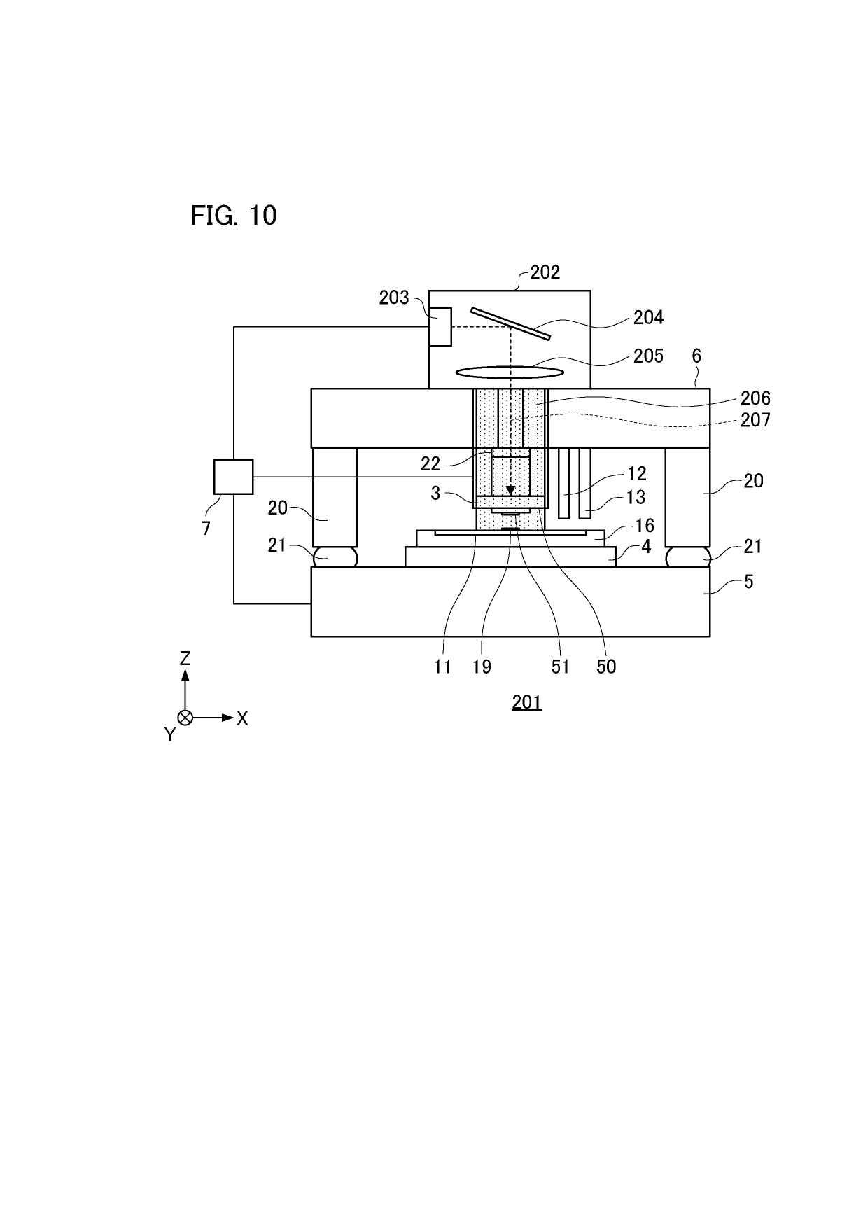

First, the configuration of the imprint apparatus used in the present embodiment will be explained with reference to FIG. 10. It should be noted that portions similar to those in FIG. 1 are denoted by the same reference numerals, and explanation thereof will be omitted. An imprint apparatus 201 has the configuration of the imprint apparatus 1 of FIG. 1, except that the light irradiation unit 2 is replaced with a light irradiation unit 202. Additionally, the mold 50 used may be the same as that in the first embodiment (see FIG. 5).

The light irradiation unit 202 has a basic configuration similar to the light irradiation unit 102 included in the imprint apparatus 101 shown in FIG. 4. The light irradiation unit 202 may include a light source 203 that generates light having a wavelength for curing the resin (photo-curable composition) 19, and a light modulation device 204 for controlling irradiation conditions of the light for the resin 19 applied at a plurality of locations on the substrate 11. The light irradiation unit 202 may further include an optical system 205 that adjusts an illuminance distribution.

The light irradiation unit 202 is controlled by the control unit 7 and, similarly to the first embodiment, is capable of irradiating light 207 only to arbitrary locations within an irradiation region 206 to cure the resin 19.

In the light irradiation unit 102 included in the imprint apparatus 101 shown in the first embodiment, since an irradiation region in one irradiation is limited to within one imprint region, imprinting and formation of the protection pattern 110 cannot be performed simultaneously.

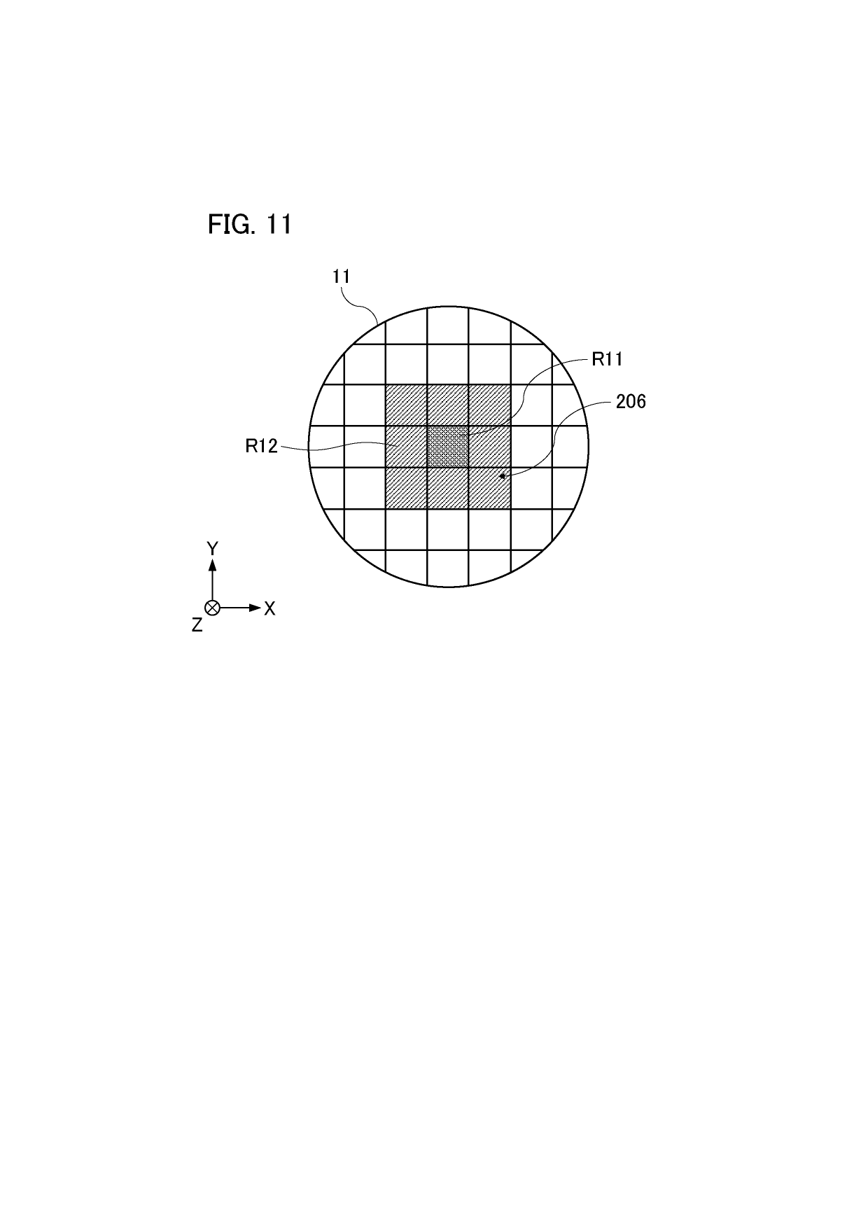

The light irradiation unit 202 in the present embodiment, as shown in FIG. 11, has an irradiation region 206 that is wider than the imprint region R11 when alignment between the mold 50 and the substrate 11 is performed in order to perform imprinting on the specific imprint region R11. FIG. 11 is a plan view of the substrate 11, in which a plurality of regions partitioned in a lattice pattern, each of which is an imprint region. That is, on the substrate, a plurality of regions in which imprint processing is executed are provided. In FIG. 11, shaded regions surrounding the imprint region R11 also serve as the irradiation region 206 of the light irradiation unit 202, and the irradiation region 206 includes a plurality of imprint regions.

Therefore, it is also possible to irradiate light 207 onto an imprint region R12, which is located around the imprint region R11 to be imprinted and is included in the irradiation region 206. The imprint region R12 is a region different from the imprint region R11 and is, for example, a region that may be a next region to be imprinted after the imprint region R11. In FIG. 11, any region included in the irradiation region 206 (a lightly shaded region) may become the imprint region R12, even if it is a region other than the region indicated by a reference sign.

The light modulation device 204 of the present embodiment can be configured as a DMD, similarly to the light modulation device 104 of the first embodiment. Additionally, the optical system 205 is an optical element that adjusts the depth of focus of light, similarly to the optical system 105. Then, in the present embodiment, for example, a wide irradiation region 206 is realized by expanding an emission range of the light source 203 and by enlarging the light modulation device 204 and the optical system 205.

Note that, in FIG. 11, although the irradiation region 206 extends to a surrounding region centered on the imprint region R11, the irradiation range 206 may be made even wider. By widening the irradiation region 206, restrictions on the order of imprinting and formation of the protection pattern 110 are reduced, and, for example, the order of processing can be flexibly determined not only with respect to adjacent regions.

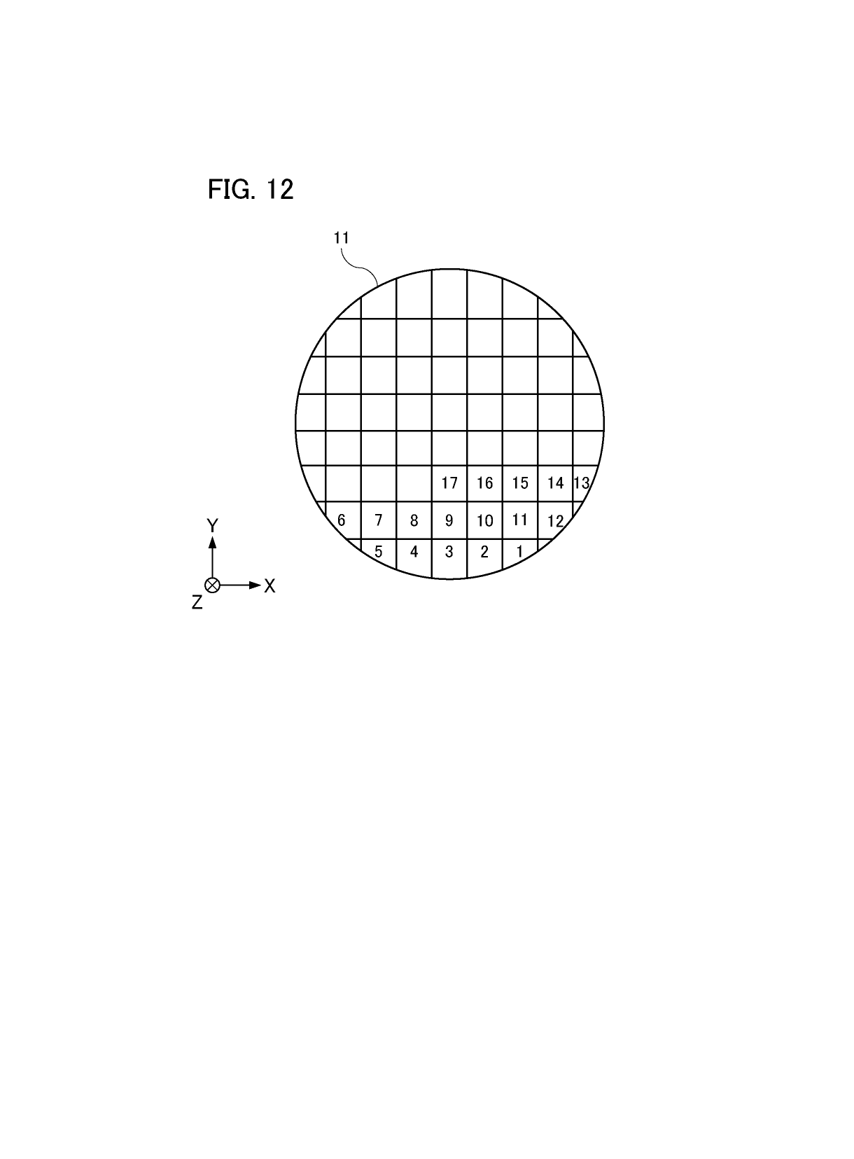

Finally, an imprint sequence in the present embodiment will be explained. In the present embodiment, pattern transfer by imprinting and formation of the protection pattern 110 are performed simultaneously. The control unit 7 controls an imprint sequence and a protection-pattern formation sequence so that imprinting and formation of the protection pattern 110 can be performed simultaneously. For example, it is assumed that imprinting and formation of the protection pattern are performed in the order shown in FIG. 12. FIG. 12 is a plan view of the substrate 11, in which a plurality of regions partitioned in a lattice pattern are each an imprint region. In FIG. 12, imprinting and formation of the protection pattern are performed in the order of numerals shown in each imprint region.

The sequence of the present embodiment will be explained with reference to FIG. 12. First, imprinting is performed in the imprint region No. 1 of FIG. 12 to transfer a pattern of the mold 50 onto the substrate 11. Thereafter, by using the coating unit 12, coating of the resin 19 onto the adjacent imprint region No. 2 is performed, and at the same time, coating of the resin 19 onto the substrate-side overlay pattern 24 of the imprint region No. 1 that has been imprinted is performed.

Then, imprinting is performed on the imprint region No. 2, and the resin 19 on the substrate-side overlay pattern 24 of the imprint region No. 1 is cured. Thus, pattern transfer in the imprint region No. 2 and formation of the protection pattern in the imprint region No. 1 can be performed simultaneously.

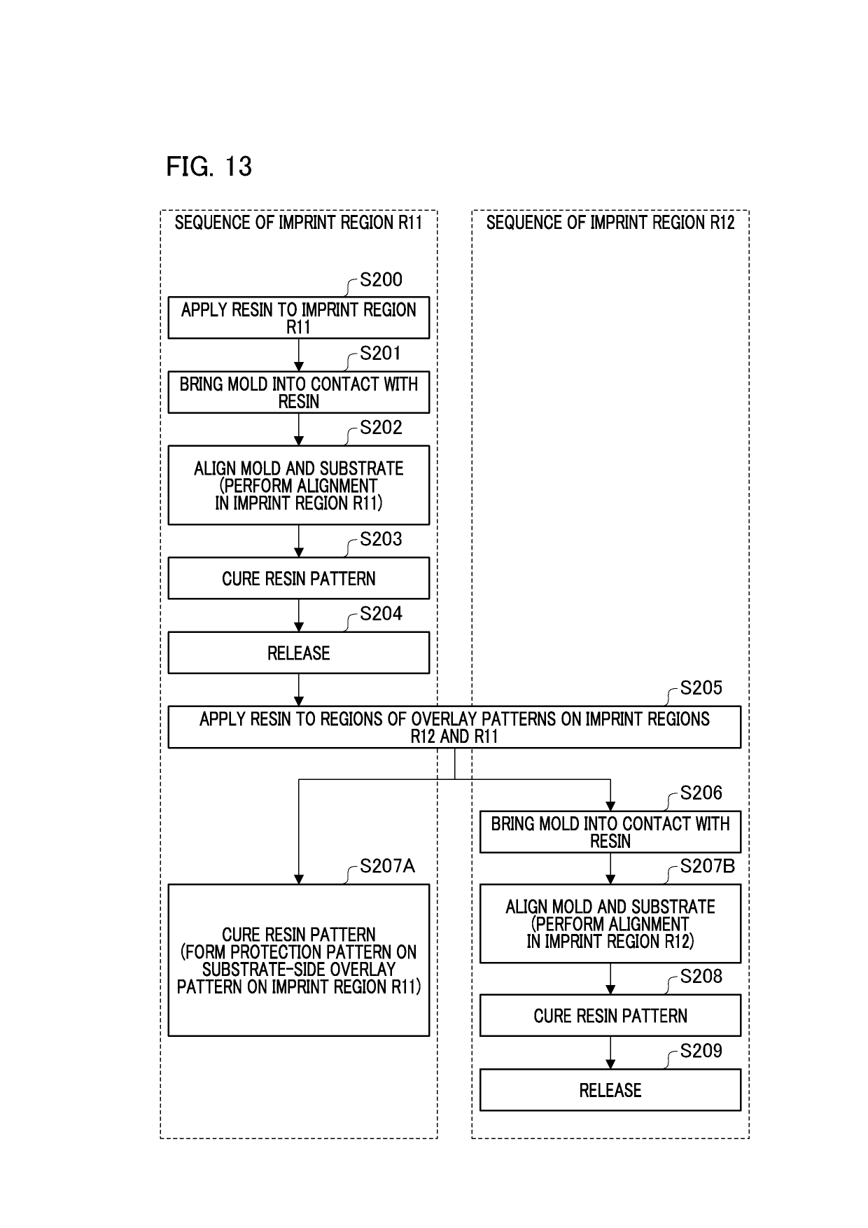

A specific sequence is explained with reference to FIG. 13. In FIG. 13, a flow is described by being divided into the imprint region R11 and the imprint region R12 explained in FIG. 11. First, in step S200, among a plurality of imprint regions of the substrate 11, the resin 19 is applied by the coating unit 12 onto an imprint region R11 to be imprinted (for example, the imprint region No. 1), for which the processing order has been determined in, for example, the order shown in FIG. 12.

In step S201, the substrate stage 4 is moved so that the imprint region R11 on which the resin 19 has been applied is positioned under the mold 50, and the mold 50 is brought into contact with the resin 19 on the imprint region R11 by the mold driving mechanism 22. As a result, the resin 19 is filled in the concave portions of the pattern region 51 of the mold 50.

In step S202, the overlay measurement unit 13 measures a relative position between a mold-side overlay pattern 53 of the mold 50 and a substrate-side overlay pattern 24 formed on the substrate 11. The control unit 7 moves the substrate stage 4 based on the measurement result to perform alignment between the pattern region 51 of the mold 50 and the imprint region R11.

In step S203, light is irradiated onto the resin 19 through the mold 50 to cure the resin 19.

In step S204, the mold 50 is separated (released) from the cured resin 19 by the mold driving mechanism 22, thereby transferring a pattern of the mold 50 to the imprint region R11.

Hereinafter, a sequence will be explained in which formation of the protection pattern in the imprint region R11 (for example, the imprint region No. 1) and imprinting in the imprint region R12 (for example, the imprint region No. 2) are performed simultaneously.

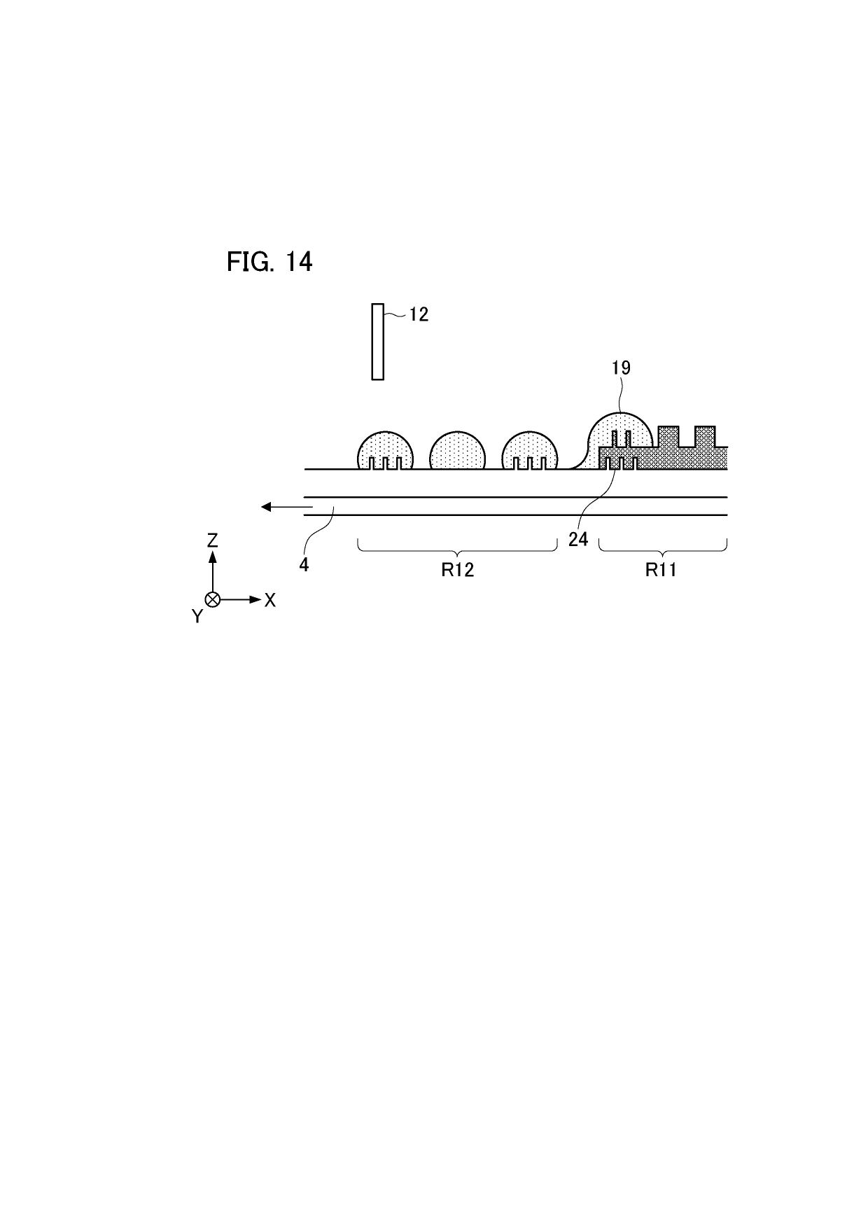

In step S205, the resin 19 is applied onto the imprint region R11 and the imprint region R12 by the coating unit 12. At this time, as shown in FIG. 14, for the imprint region R11, the resin 19 is applied only onto the region of the substrate-side overlay pattern 24, similarly to the protection-pattern formation method explained in the first embodiment. For the imprint region R12, the resin 19 necessary for transferring a pattern of the mold 50 is applied, similarly to step S200. At this time, the application amount and position of the resin 19 may be different from those in step S200. That is, in the explanation of this flowchart, the imprint region R11 becomes a second region, and the imprint region R12 becomes a first region.

That is, the control unit 7 causes a curable composition to be applied to the first region for imprint processing, and also causes a curable composition to be applied to a first alignment mark portion of the second region in which imprint processing has been completed, for formation of a protection pattern.

In step S206, the substrate stage 4 is moved so that the imprint region R12 is positioned under the mold 50, and the mold 50 is brought into contact with the resin 19 on the imprint region R12 by the mold driving mechanism 22.

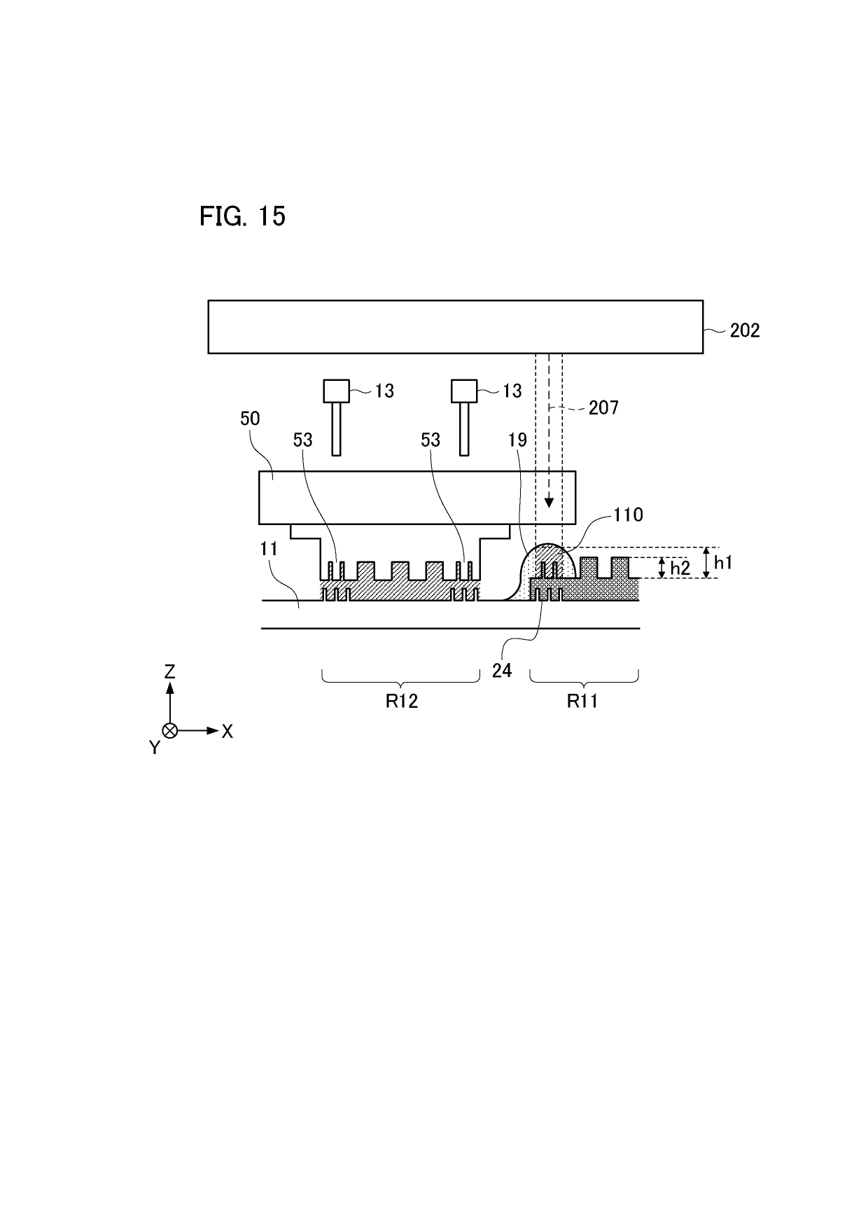

In step S207B, the overlay measurement unit 13 measures a relative position between a mold-side overlay pattern 53 of the mold 50 and a substrate-side overlay pattern 24 formed in the imprint region R12 (see FIG. 15). The control unit 7 moves the substrate stage 4 based on the measurement result to perform alignment between the pattern region 51 of the mold 50 and the imprint region R12.

On the other hand, in step S207A, as shown in FIG. 15, since the imprint region R11 is located within the irradiation region 206 of the light irradiation unit 202, the light 207 is irradiated only onto a portion directly above the substrate-side overlay pattern 24 within the imprint region R11, thereby curing the resin 19. Thus, the protection pattern 110 is formed only directly above the substrate-side overlay pattern 24 within the imprint region R11, and the uncured resin 19 in the imprint region R11 disappears by volatilization.

Thus, by executing step S207A and step S207B in parallel, it becomes possible to perform transfer of a pattern of the mold 50 in the imprint region R12 and, at the same time, cure the resin 19 in the imprint region R11 to form the protection pattern 110.

In step S208, light is irradiated onto the resin 19 in the imprint region R12 through the mold 50 to cure the resin 19.

In step S209, the mold 50 is separated (released) from the cured resin 19A by the mold driving mechanism 22, thereby transferring a pattern of the mold 50 to the imprint region R12.

In the above description, although irradiation of light 207 for forming the protection pattern 110 is performed as step S207A, the timing is not limited thereto. After the overlay measurement unit 13 performs alignment in step S207B by measuring a relative position between the mold-side overlay pattern 53 and the substrate-side overlay pattern 24, it is sufficient that irradiation be performed before separation of the mold 50 is started in step S209. That is, irradiation of light to the curable composition applied to the second region may be performed during a period after alignment between the mold and the substrate is performed in the first region and before the mold is released. Therefore, irradiation of light (S207A) to the curable composition applied to the second region may be performed simultaneously with irradiation of light (S208) in the first region.

Incidentally, when the sequence is performed in the order shown in FIG. 12, the positional relation between the imprint region R12 in which step S207B is performed and the imprint region R11 in which step S207A is performed may be different.

For example, in FIG. 12, when imprinting is performed in the imprint region No. 2, the imprint region No. 1 in which the protection pattern 110 is formed is located on the right side. In contrast, when imprinting is performed in the imprint region No. 6, the imprint region No. 5 in which the protection pattern 110 is formed is located at the lower right side. The light irradiation unit 202 has an irradiation region 206 so as to surround a region in which imprinting is performed, as shown in FIG. 11. Therefore, even in a case in which a positional relation between a region in which imprinting is performed and a region in which the protection pattern 110 is formed is different, imprinting and formation of the protection pattern 110 can be performed simultaneously.

By repeating the above sequence, transfer of a pattern by imprinting and formation of the protection pattern 110 can be performed simultaneously, thereby shortening process time.

### Third Embodiment

Next, a third embodiment will be explained. In the first and second embodiments, the resin 19 is applied only onto the substrate-side overlay pattern 24 by dispensing with the coating unit 12, thereby forming the protection pattern 110. In the present embodiment, a method will be explained in which a photo-curable resin is preliminarily applied onto an entire surface of an imprinted substrate, and thereafter, a protection pattern is formed on the overlay pattern by exposure and development processing.

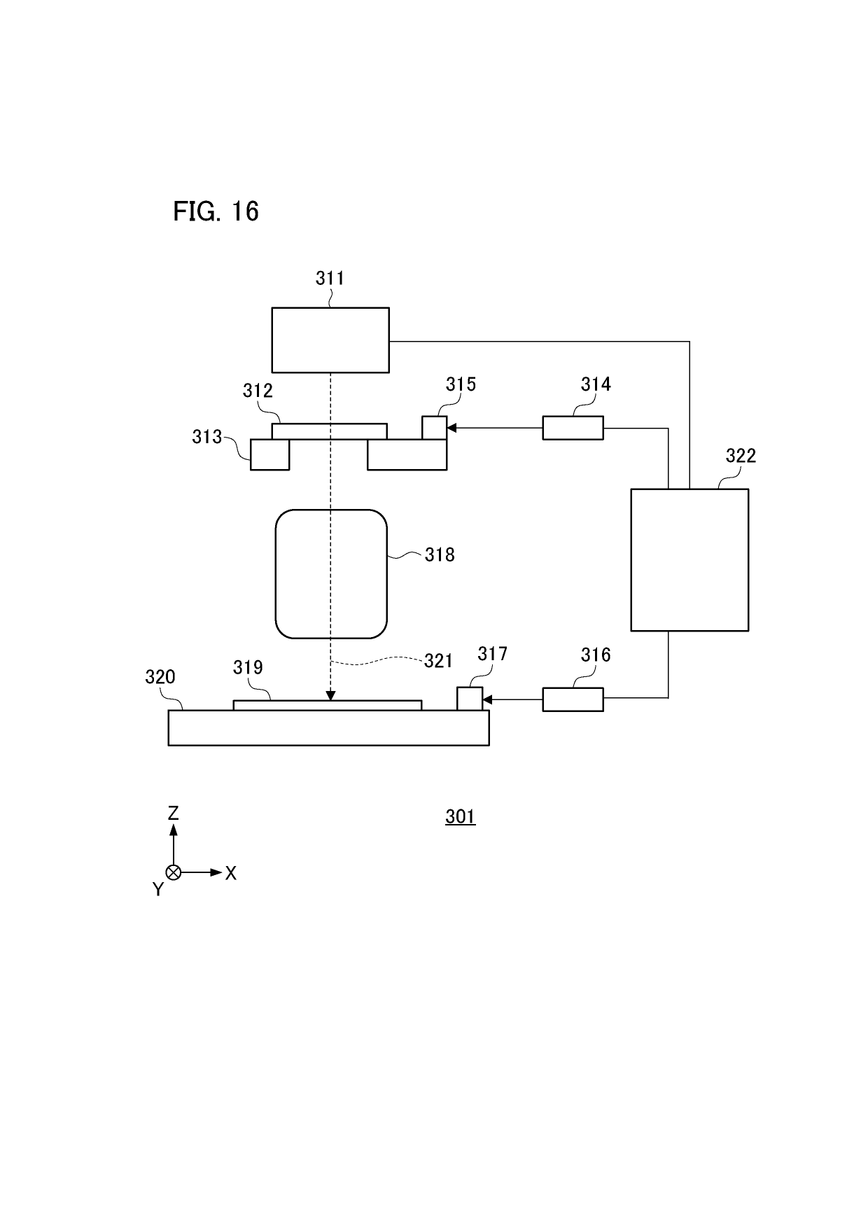

FIG. 16 is a schematic diagram illustrating a configuration of the exposure apparatus 301. The exposure apparatus 301 is used in a lithography process, which is a manufacturing process for a device such as a semiconductor device, and is a lithography apparatus that forms a pattern on a substrate by using an original (also referred to as a reticle or a mask). That is, the exposure apparatus 301 transfers a pattern of an original onto each of a plurality of regions of the substrate by exposing the substrate.

As shown in FIG. 16, the exposure apparatus 301 includes an illumination optical system 311, an original stage 313 that holds an original 312, a projection optical system 318, a substrate stage 320 that holds a substrate 319, a first measurement unit 314, a second measurement unit 316, and a control unit 322.

The control unit 322 is configured by, for example, a computer (information processing apparatus) including a CPU and a memory, and is connected to respective components of the exposure apparatus 301 via communication lines. The control unit 322 executes control of the respective components according to a program or the like, and controls, for example, an exposure process of irradiating the light 321 onto the substrate 319 through the original 312. The control unit 322 may be disposed integrally with other components of the exposure apparatus 301 (within a shared housing), or may be disposed separately from the other components of the exposure apparatus 301 (within a different housing).

The illumination optical system 311 includes a light shielding member such as a masking blade, and shapes light 321 emitted from a light source (not illustrated), such as an excimer laser, into slit light, thereby illuminating a part of the original 312.

The original 312 is held by the original stage 313 and the substrate 319 is held by the substrate stage 320, and the original 312 and the substrate 319 are disposed at optically conjugate positions via the projection optical system 318.

The projection optical system 318 has a predetermined projection magnification (for example, 1/2 or 1/4), and projects a pattern formed on the original 312 onto the substrate 319.

The original stage 313 and the substrate stage 320 are configured to be drivable in a direction perpendicular to the optical axis of the projection optical system 318 (an optical axis of slit light) (in the Y-axis direction or the X-axis direction).

The first measurement unit 314 includes, for example, a laser interferometer, and measures a displacement of the original stage 313 from a reference position by irradiating laser light onto a reflector 315 provided on the original stage 313 and detecting the laser light reflected by the reflector 315. The first measurement unit 314 can obtain a current position of the original stage 313 based on the measured displacement.

The second measurement unit 316 includes, for example, a laser interferometer, and measures a displacement of the substrate stage 320 from a reference position by irradiating laser light onto a reflector 317 provided on the substrate stage 320 and detecting the laser light reflected by the reflector 317. The second measurement unit 316 can obtain a current position of the substrate stage 320 based on the measured displacement.

The control unit 322 controls driving of the original stage 313 and the substrate stage 320 in the X-axis direction and the Y-axis direction, based on the current position of the original stage 313 obtained by the first measurement unit 314 and the current position of the substrate stage 320 obtained by the second measurement unit 316. That is, the substrate stage 320 functions as a driving unit that drives the substrate so as to perform alignment between the substrate and the original plate based on the pattern of the original.

Note that, in the present embodiment, although each of the first measurement unit 314 and the second measurement unit 316 uses a laser interferometer to measure a position of the original stage 313 and a position of the substrate stage 320, the present disclosure is not limited thereto, and, for example, an encoder may be used.

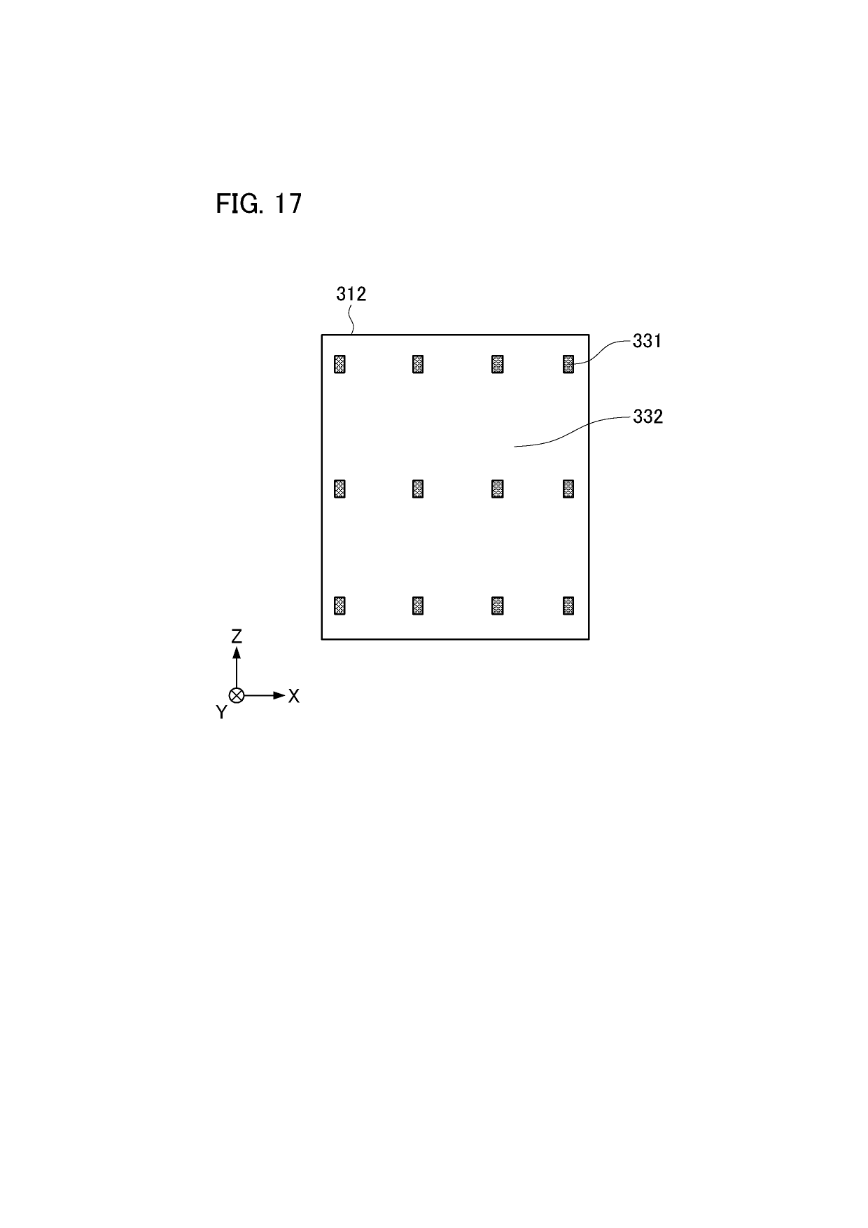

Next, a protection-pattern forming method using the exposure apparatus 301 will be explained. FIG. 17 is a plan view illustrating the original 312. The original 312 has a light shielding area 331 that blocks light 321 and a transmissive region 332 that transmits the light 321.

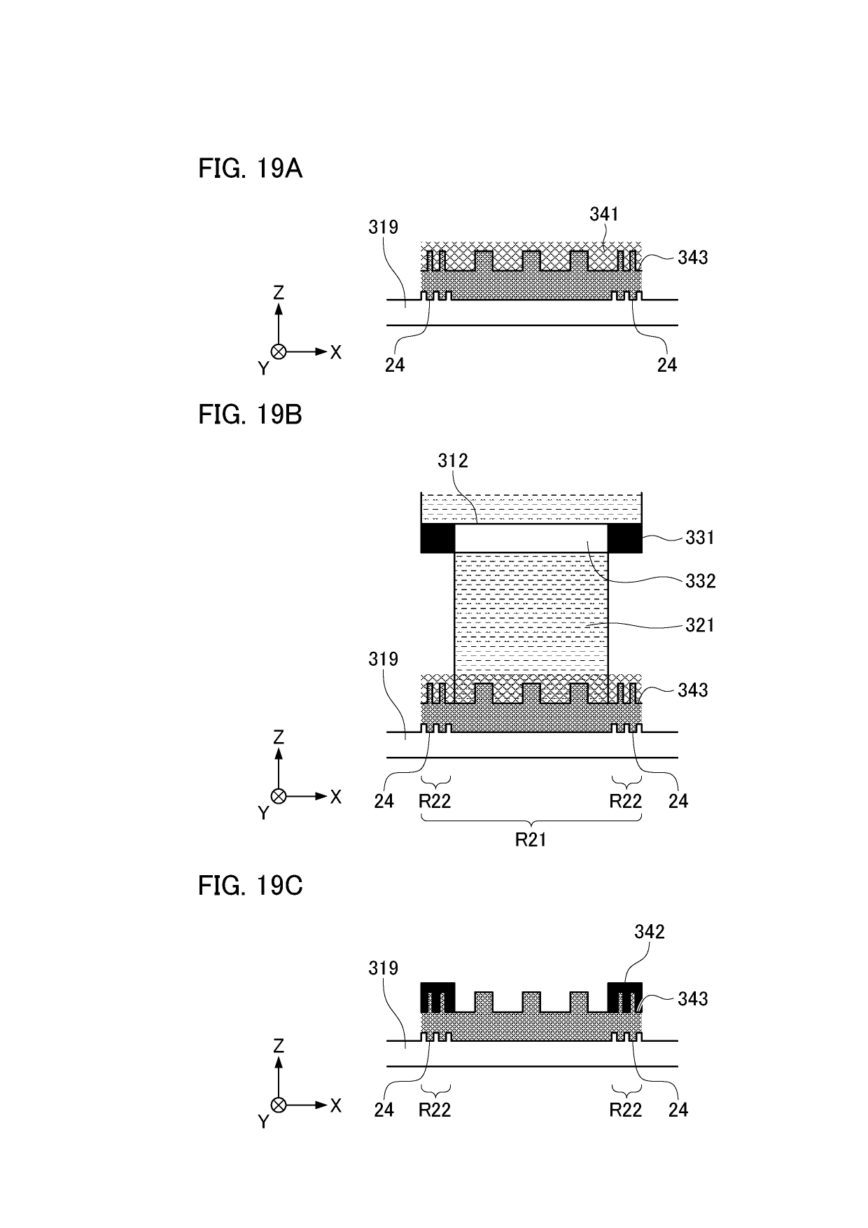

The original 312 is held by the original stage 313 and is aligned so as to be located directly above an arbitrary imprint region in which a protection pattern is to be formed. The light shielding area 331 is designed so that, after alignment, the light 321 irradiated through the original 312 does not contact the substrate-side overlay pattern 24 (alignment mark) in the imprint region in which the protection pattern is to be formed, for example, as shown in FIGS. 19A and 19C.

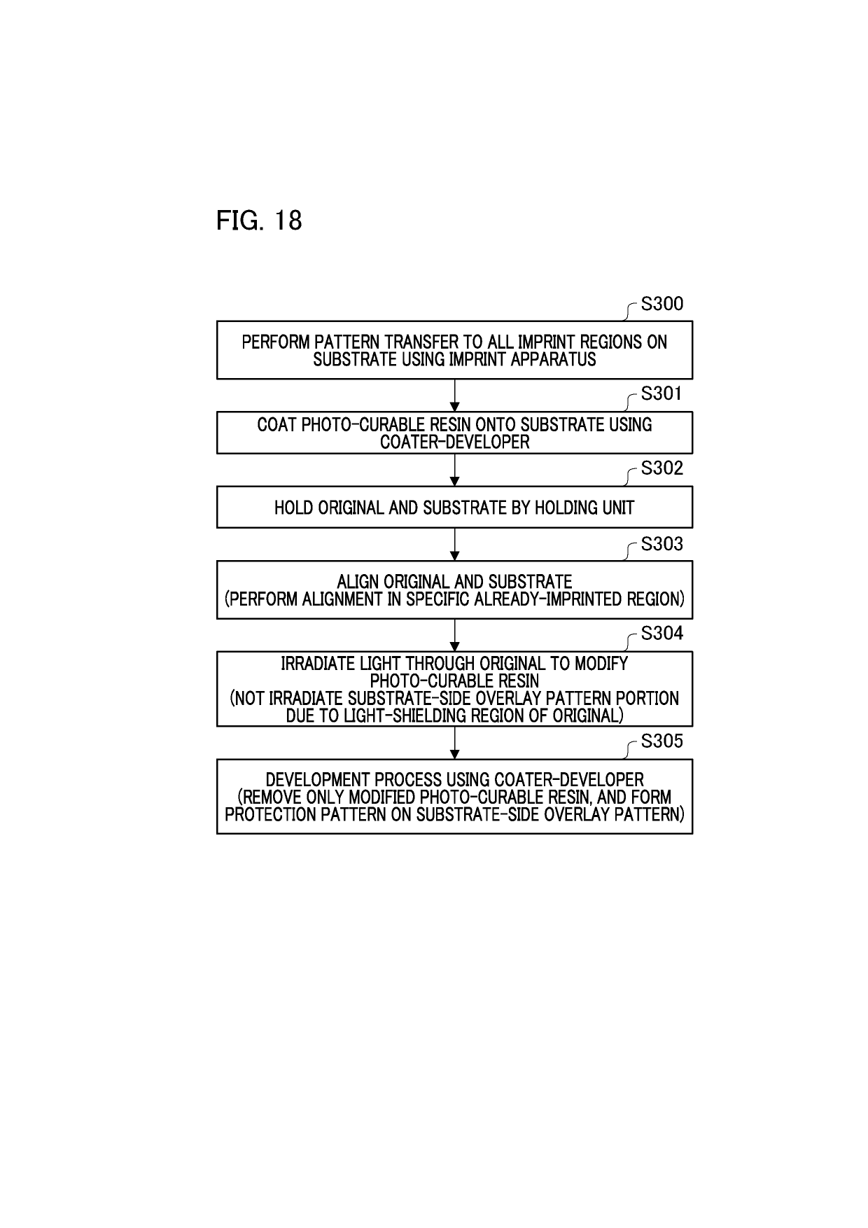

Hereinafter, with reference to FIG. 18, a sequence (method) for forming a protection pattern will be explained. First, in step S300, the pattern of the mold 50 is transferred onto all imprint regions on the substrate 319, based on the imprint method explained in steps S100 to S104 of FIG. 9 in the first embodiment. Step S300 is performed by an imprint apparatus other than the exposure apparatus 301.

In step S301, as shown in FIG. 19A, in a coater/developer separate from the exposure apparatus 301, a photo-curable resin 341 is applied onto a pattern transfer surface 343 of the substrate 319.

In step S302, the original 312 is held by the original stage 313 and the substrate 319 is held by the substrate stage 320.

In step S303, as shown in FIG. 19B, alignment is performed so that an arbitrary imprint region R21, in which a protection pattern is to be first formed on the substrate 319, is positioned directly below the light shielding area 331 of the original 312.

In step S304, as shown in FIG. 19B, the light 321 is irradiated onto the substrate 319 from the illumination optical system 311. The light 321 passes through the transmission region 332 of the original 312, is irradiated onto the substrate 319, and modifies the photo-curable resin 341. At this time, the photo-curable resin 341 present on a region R22 in which the substrate-side overlay pattern 24 has been formed is not modified, because light is blocked by the light shielding area 331 and the light 321 is not irradiated onto the region. That is, the original 312 functions as a restricting unit that restricts projection from the projection optical system to portions other than the alignment-mark portion.

The above alignment and light irradiation are performed for all imprint regions, thereby modifying the photo-curable resin 341 present in regions other than the region R22 on the substrate 319.

Finally, in step S305, as shown in FIG. 19C, development is performed using a coater/developer, whereby a protection pattern 342 is formed on the substrate-side overlay pattern 24 by removing the modified photo-curable resin 341.

By carrying out the present embodiment, the protection pattern 342 can be formed by the exposure apparatus 301. Therefore, it is possible to form the protection pattern while using a conventional imprint apparatus.

### Embodiment of Method of Manufacturing an Article

A pattern of a cured product formed by using an imprint apparatus is employed either permanently in at least a part of various articles, or temporarily during the manufacture of various articles. The article is, for example, an electric circuit element, an optical element, a MEMS, a recording element, a sensor, or a mold. Examples of the electric circuit element include volatile or nonvolatile semiconductor memories such as DRAM, SRAM, flash memory, and MRAM, and semiconductor devices such as an LSI, a CCD, an image sensor, and an FPGA. Examples of the mold include a mold for imprinting.

The pattern of the cured product is used either as it is as at least a part of a component member of the above articles, or temporarily as a resist mask. After etching, ion implantation, or the like is performed in a processing step of the substrate, the resist mask is removed.

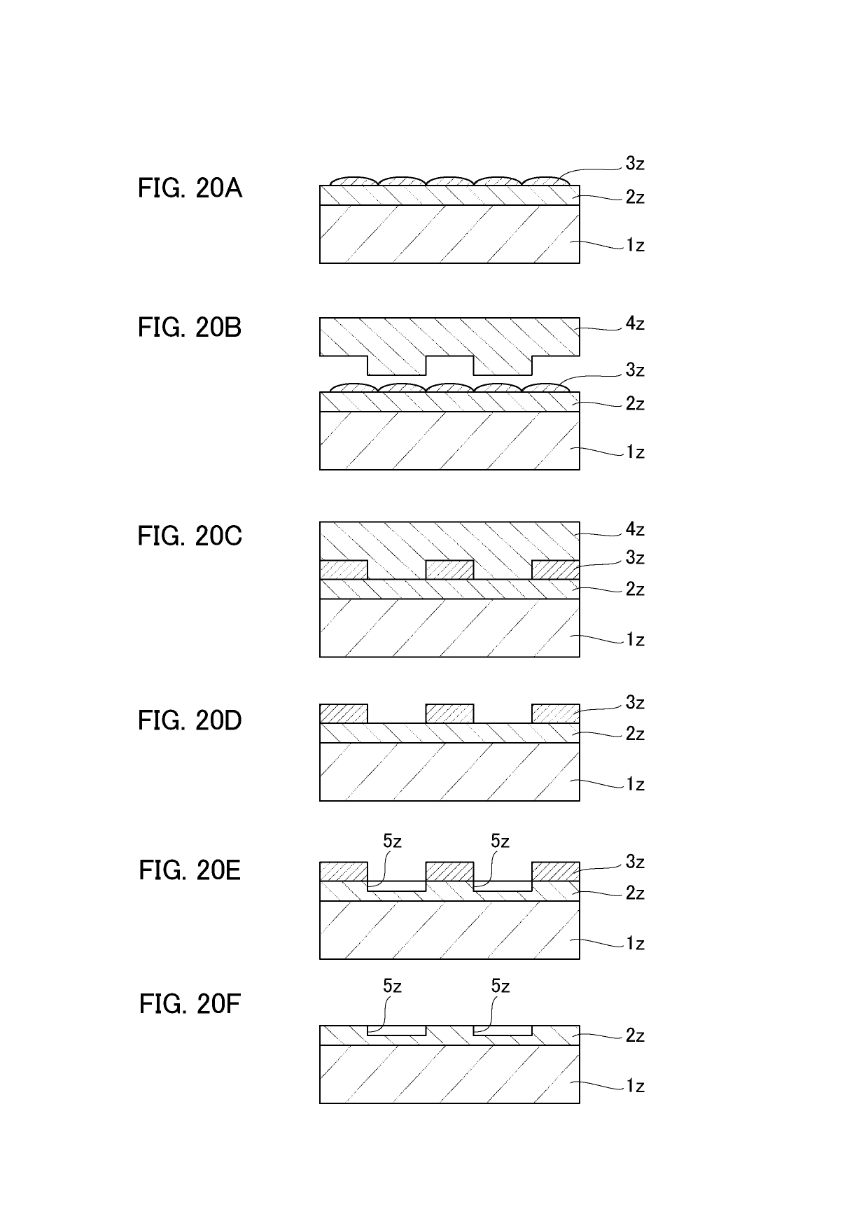

Next, a specific method for manufacturing an article will be explained. As shown in FIG. 20A, a substrate 1z such as a silicon wafer, on a surface of which a material to be processed 2z such as an insulating material has been formed, is prepared, and subsequently, a composition 3z is applied onto the surface of the material to be processed 2z by an inkjet method and the like. Here, a state is illustrated in which a plurality of droplet-shaped compositions 3z have been applied onto the substrate.

As shown in FIG. 20B, a mold 4z for imprinting is opposed to the composition 3z on the substrate, with a side on which its concave-convex pattern has been formed facing the composition 3z. As shown in FIG. 20C, the substrate 1z to which the composition 3z has been applied and the mold 4z are brought into contact with each other, and pressure is applied. The composition 3z is filled in a gap between the mold 4z and the material to be processed 2z. In this state, when light serving as curing energy is irradiated through the mold 4z, the composition 3z is cured.

As shown in FIG. 20D, after the composition 3z is cured, when the mold 4z and the substrate 1z are separated, a pattern of a cured product of the composition 3z is formed on the substrate 1z. The pattern of the cured product has a shape in which a concave portion of the mold corresponds to a convex portion of the cured product, and a convex portion of the mold corresponds to a concave portion of the cured product, that is, the concave-convex pattern of the mold 4z is transferred to the composition 3z.

As shown in FIG. 20E, when etching is performed using the pattern of the cured product as an etching-resistant mask, on the surface of the material to be processed 2z, portions where the cured product is absent or remains thin are removed, thereby forming a groove 5z. As shown in FIG. 20F, when the pattern of the cured product is removed, an article having the groove 5z formed on the surface of the material to be processed 2z can be obtained. Here, although the pattern of the cured product is removed, the pattern may also be left unremoved even after processing and used, for example, as a film for interlayer insulation included in a semiconductor element, that is, as a component member of the article. Note that although an example has been described in which, as the mold 4z, a mold for circuit-pattern transfer provided with a concave-convex pattern is used, the mold may also be a mold (planar template) having a planar portion with no concave-convex pattern.

### Other Embodiments

Embodiment(s) of the present disclosure can also be realized by a computer of a system or apparatus that reads out and executes computer executable instructions (e.g., one or more programs) recorded on a storage medium (which may also be referred to more fully as a 'non-transitory computer-readable storage medium') to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)TM), a flash memory device, a memory card, and the like.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

According to the present disclosure, during imprint, the region of the overlay mark on the substrate side can be minimized.

This application claims the benefit of Japanese Patent Application No. 2024-220250, filed December 16, 2024, which is incorporated herein by reference in its entirety.

What is claimed is:

1. An imprint apparatus configured to perform an imprint process of forming a pattern in a curable composition on a substrate by using a mold, the imprint apparatus comprising:
a coating unit configured to apply the curable composition to the substrate on which a first alignment mark has been formed;
a driving unit configured to drive at least one of the mold on which a second alignment mark has been formed and the substrate;
an irradiation unit configured to irradiate light for curing the curable composition;
a restricting unit configured to restrict an irradiation range of the light irradiated from the irradiation unit; and
a control unit configured to, after the imprint process, perform control such that the coating unit applies the curable composition to the first alignment-mark portion, the restricting unit restricts the irradiation range to the first alignment-mark portion, and the irradiation unit irradiates the light to form a protection pattern that protects the first alignment mark.

2. The imprint apparatus according to claim 1, wherein the control unit causes the coating unit to apply the curable composition such that the protection pattern completely covers a region on the substrate in which the first alignment mark has been formed.

3. The imprint apparatus according to claim 1, wherein the control unit forms the protection pattern such that the protection pattern does not overlap with a pattern region formed by the imprint process.

4. The imprint apparatus according to claim 1, wherein the control unit forms a pattern height of the protection pattern higher than a pattern height of the pattern formed by the imprint process.

5. The imprint apparatus according to claim 1, wherein, after formation of the protection pattern, the control unit causes the coating unit to apply the curable composition again to the first alignment-mark portion, and causes the irradiation unit to irradiate the light while causing the restricting unit to limit the irradiation range to the first alignment-mark portion.

6. The imprint apparatus according to claim 1, wherein the control unit sets an exposure amount of the light irradiated by the irradiation unit during formation of the protection pattern greater than an exposure amount of light irradiated in the imprint process.

7. The imprint apparatus according to claim 1, wherein the restricting unit includes a light modulation element in which micro-mirrors arranged in a plane modulate the light by reflecting or shielding the light.

8. The imprint apparatus according to claim 1,
wherein a plurality of regions for executing the imprint process are provided on the substrate, and
wherein the control unit causes the curable composition to be applied for the imprint process onto a first region, and causes the curable composition to be applied, for formation of the protection pattern, onto a first alignment-mark portion of a second region that is different from the first region and in which the imprint process has been completed.

9. The imprint apparatus according to claim 8, wherein the irradiation range of the light irradiated from the irradiation unit includes the plurality of regions.

10. The imprint apparatus according to claim 8, wherein the control unit causes irradiation of the light onto the curable composition applied to the second region to be executed during a period from when alignment between the mold and the substrate is performed in the first region until the mold is released.

11. The imprint apparatus according to claim 10, wherein the control unit causes the irradiation of the light onto the curable composition applied to the second region to be executed simultaneously with irradiation of the light in the first region.

12. An exposure apparatus configured to transfer a pattern of an original onto each of a plurality of regions of a substrate by exposing the substrate, the exposure apparatus comprising:
a driving unit configured to drive the substrate, on which an alignment mark has been formed and a curable composition has been coated on a surface, to align the substrate with the original based on the pattern;
a projection optical system configured to project the pattern of the original onto the substrate; and
a restricting unit configured to restrict projection from the projection optical system to a portion other than the alignment-mark portion.

13. The exposure apparatus according to claim 12, wherein the restricting unit restricts the projection to a portion other than the alignment-mark portion based on the pattern of the original.

14. An imprint method for forming, by use of a mold, a pattern of a curable composition on a substrate, the method comprising:
applying the curable composition to the substrate on which a first alignment mark has been formed;
driving at least one of the mold on which a second alignment mark has been formed and the substrate;
irradiating light for curing the curable composition to form the pattern; and
applying the curable composition to the first alignment-mark portion after irradiation of the light, restricting an irradiation range of the light to the first alignment-mark portion, and irradiating the light, to form a protection pattern that protects the first alignment mark.

15. A manufacturing method of an article comprising:
forming a pattern on a substrate by using the imprint apparatus according to claim 1;
processing the substrate on which the pattern has been formed; and
manufacturing an article from the processed substrate.
